(19) United States
(12) Patent Application Publication
(10) Pub. No.: US 2025/0019517 A1
(43) Pub. Date: Jan. 16, 2025

(54) RESIN COMPOSITION, PREPREG, RESIN SHEET, LAMINATE, METAL FOIL-CLAD LAMINATE, AND PRINTED WIRING BOARD

(71) Applicant: MITSUBISHI GAS CHEMICAL COMPANY, INC., Tokyo (JP)

(72) Inventors: Tatsuro TAKAMURA, Tokyo (JP); Naoki KASHIMA, Tokyo (JP); Shohei YAMAGUCHI, Tokyo (JP); Sayaka ITO, Tokyo (JP); Yoshihiro NAKAZUMI, Tokyo (JP); Yuji YAMAGATA, Tokyo (JP); Narihiro URAHAMA, Tokyo (JP); Kazuki SUNAKAWA, Fukushima (JP); Naoya TOKUNAGA, Tokyo (JP); Tetsuro MIYAHIRA, Tokyo (JP); Takaaki OGASHIWA, Tokyo (JP)

(73) Assignee: MITSUBISHI GAS CHEMICAL COMPANY, INC., Tokyo (JP)

(21) Appl. No.: 18/692,999

(22) PCT Filed: Oct. 19, 2022
(86) PCT No.: PCT/JP2022/038876

§ 371 Date: Mar. 18, 2024

(30) Foreign Application Priority Data
Oct. 26, 2021 (JP) 2021-174971

(51) Int. Cl. C08K 3/22; C08J 5/18; C08J 5/24; C08L 63/00

(52) U.S. Cl. CPC C08K 3/22; C08J 5/18; C08J 5/24; C08L 63/00; C08J 2363/00; C08K 2003/2206; C08K 2003/2241; C08K 2201/001; C08K 2201/005; C08L 2203/20

(57) ABSTRACT

An object is to provide a resin composition having a high permittivity and a low dissipation factor, and having low water absorption, favorable thermal characteristics, a high glass transition temperature, a high peel strength of the metal foil, and a low coefficient of thermal expansion, and suitably used for producing an insulation layer of a printed wiring board; and a prepreg, a resin sheet, a laminate, a metal foil-clad laminate, and a printed wiring board obtainable by using the resin composition. The resin composition of the present invention contains: (A) a dielectric powder, (B) a cyanate ester compound, and (C) an epoxy compound, wherein a functional group equivalent ratio of a cyanate group of the cyanate ester compound (B) to an epoxy group of the epoxy compound (C) (cyanate group/epoxy group) is 0.1 to 2.0.

### TECHNICAL FIELD

The present invention relates to a resin composition, a prepreg, a resin sheet, a laminate, a metal foil-clad laminate, and a printed wiring board.

### BACKGROUND ART

In recent years, signal bands for information and telecommunication device such as PHS, and mobile phones, and CPU clock time of computers have reached the GHz band, and thus the frequency has been higher. A dielectric loss of an electrical signal is proportionate to the product of a square root of a relative permittivity and a dissipation factor of an insulation layer forming a circuit, and a frequency of the electrical signal. For this reason, the higher a frequency of a signal used, the greater a dielectric loss becomes. An increase in the dielectric loss dampens an electrical signal to undermine the reliability of the signal. It is necessary for preventing this to select a material having low permittivity and dissipation factor for an insulation layer.

On the other hand, for an insulation layer of a high frequency circuit, there are demands for formation of a delay circuit, impedance matching of a wiring board in a low impedance circuit, a finer wiring pattern, and a circuit more complex with a substrate having a built-in capacitor, and there is a case where an insulation layer with a higher permittivity is required. For this reason, electronic components in which an insulation layer having a high permittivity and a low dissipation factor is used have been proposed (e.g., Patent Document 1). An insulation layer having a high permittivity and a low dissipation factor is formed by dispersing a filler such as a ceramic powder and an insulated metal powder in a resin.

For the insulation layer, for example, a resin composition that includes a cyanate ester compound in combination with an epoxy compound is used due to excellent heat resistance, electrical properties and the other properties.

### CITATION LIST

### Patent Document

Patent Document 1: Japanese Patent Laid-Open No. 2000-91717

### SUMMARY OF INVENTION

### Technical Problem

For increasing the relative permittivity of an insulation layer, a filler having a high relative permittivity is required to be blended; however a dissipation factor also simultaneously increases, thereby posing the problem of a higher transmission loss of a higher frequency signal.

Additionally, the filler used for producing the insulation layer having a high permittivity and a low dissipation factor forms voids depending on the filler blended, and causes delamination when producing a laminate. For this reason, such a filler poses the problem of the poor thermal characteristics and dielectric characteristics (high permittivity and low dissipation factor) in a printed wiring board and the like.

Further, the insulation layer obtained by using an epoxy compound poses the problem of an insufficient peel strength of the metal foil (e.g., copper foil peel strength) when incorporated into a metal foil-clad laminate.

Furthermore, an insulation layer with a low glass transition temperature (Tg) and a high coefficient of thermal expansion causes warpage and interfacial delamination when producing a laminate. For this reason, it is also important that the resin composition for a printed wiring board and the like form a cured product having a high glass transition temperature and a low coefficient of thermal expansion.

The present invention has been made to solve the problems described above and has aimed to provide a resin composition having a high permittivity and a low dissipation factor, and having low water absorption, favorable thermal characteristics, a high glass transition temperature, a high peel strength of the metal foil, and a low coefficient of thermal expansion, and suitably used for producing an insulation layer of a printed wiring board; and a prepreg, a resin sheet, a laminate, a metal foil-clad laminate, and a printed wiring board obtainable by using the resin composition.

Specifically, the present invention is as follows.
[1] A resin composition containing:
   (A) a dielectric powder,
   (B) a cyanate ester compound, and
   (C) an epoxy compound,
   wherein a functional group equivalent ratio of a cyanate group of the cyanate ester compound (B) to an epoxy group of the epoxy compound (C) (cyanate group/epoxy group) is 0.1 to 2.0.
[2] The resin composition according to [1], wherein the dielectric powder (A) contains one or more selected from the group consisting of titanium dioxide, barium titanate, calcium titanate, and strontium titanate.
[3] The resin composition according to [1] or [2], wherein a median particle size of the dielectric powder
   (A) is 0.1 to 5 μm.
[4] The resin composition according to any of [1] to [3], wherein a content of the dielectric powder (A) is 50 to 500 parts by mass based on 100 parts by mass of a total resin solid content in the resin composition.
[5] The resin composition according to any of [1] to [4], wherein the cyanate ester compound (B) contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, and biphenyl aralkyl-type cyanate ester compounds.
[6] The resin composition according to any of [1] to [5], wherein the epoxy compound (C) contains one or more selected from the group consisting of biphenyl aralkyl-type epoxy resins, naphthalene-type epoxy resins, naphthylene ether-type epoxy resins, and butadiene backbone-containing epoxy resins.
[7] The resin composition according to any of [1] to [6], further containing one or more thermosetting resins or compounds selected from the group consisting of maleimide compounds, modified polyphenylene ether compounds, phenolic compounds, alkenyl-substituted nadiimide compounds, oxetane resins, benzoxazine compounds, and compounds having a polymerizable unsaturated group.
[8] The resin composition according to any of [1] to [7], further containing a filler different from the dielectric powder (A).
[9] The resin composition according to [8], wherein the filler contains one or more selected from the group consisting of silica, alumina, talc, aluminum nitride, boron nitride, boehmite, aluminum hydroxide, zinc molybdate, silicone rubber powder, and silicone composite powder.
[10] The resin composition according to [8] or [9], wherein a content of the filler is 50 to 300 parts by mass based on 100 parts by mass of a total resin solid content in the resin composition.
[11] The resin composition according to any of [1] to [10], for use in a printed wiring board.
[12] A prepreg, containing:
   a base material, and
   the resin composition according to any of [1] to [11] penetrating or coating the base material.
[13] A resin sheet containing the resin composition according to any of [1] to [11].
[14] A laminate containing one or more selected from the group consisting of the prepreg according to [12], and the resin sheet according to [13].
[15] A metal foil-clad laminate, containing:
   the laminate according to [14], and
   a metal foil disposed on one side or each of both sides of the laminate.
[16] A printed wiring board, containing an insulation layer, and a conductor layer disposed on one side or each of both sides of the insulation layer, wherein the insulation layer contains a cured product of the resin composition according to any of [1] to [11].

### Advantageous Effects of Invention

The resin composition of the present invention can accordingly provide a resin composition having a high permittivity and a low dissipation factor, and having low water absorption, favorable thermal characteristics, a high glass transition temperature, a high peel strength of the metal foil, and a low coefficient of thermal expansion, and suitably used for producing an insulation layer of a printed wiring board; and a prepreg, a resin sheet, a laminate, a metal foil-clad laminate, and a printed wiring board obtainable by using the resin composition.

### DESCRIPTION OF EMBODIMENTS

Hereinafter, embodiments to carry out the present invention (hereinafter, referred to as the “present embodiment”) will be described in more detail. The following present embodiments are examples to illustrate the present invention and do not intend to limit the present invention to the contents below. The present invention can be carried out with appropriate modifications within the scope of the spirit thereof.

In the present embodiments, the “resin solid content” or the “resin solid content in the resin composition” refers to the resin components of the resin composition, excluding dielectric powder (A), the filler, additives (a silane coupling agent, a wetting and dispersing agent, a curing accelerator, and other components) and a solvent, unless otherwise noticed. The “100 parts by mass of the total resin solid content” or the “100 parts by mass of the total resin solid content in the resin composition” means that the total amount of the resin components of the resin composition, excluding dielectric powder (A), the filler, additives (a silane coupling agent, a wetting and dispersing agent, a curing accelerator, and other components) and a solvent, is regarded as 100 parts by mass.

### [Resin Composition]

The resin composition of the present embodiment contains: (A) a dielectric powder, (B) a cyanate ester compound, and (C) an epoxy compound, wherein a functional group equivalent ratio of a cyanate group of the cyanate ester compound (B) to an epoxy group of the epoxy compound (C) (cyanate group/epoxy group) is 0.1 to 2.0.

In the present embodiments, since the resin composition contains (A) a dielectric powder, (B) a cyanate ester compound, and (C) an epoxy compound, wherein a functional group equivalent ratio of a cyanate group of the cyanate ester compound (B) to an epoxy group of the epoxy compound (C) (cyanate group/epoxy group) is 0.1 to 2.0, it is possible to obtain a cured product having a high permittivity and a low dissipation factor, and having low water absorption, favorable thermal characteristics, a high glass transition temperature, a high peel strength of the metal foil, and a low coefficient of thermal expansion, and suitable for an insulation layer of a printed wiring board. The reason is not clear but the present inventors infer as follows.

A cured product of a resin composition that includes a cyanate ester compound in combination with an epoxy compound has extremely excellent heat resistance and electrical properties.

However, in a resin composition including a dielectric powder with a cyanate ester compound and an epoxy compound, the dielectric powder reacts to the cyanate group of the cyanate ester compound due to Lewis acidity thereof, thereby increasing the electrophilicity and easily reacting to moisture. For this reason, the cyanate ester compound is easily hydrolyzed, and a cured product of the resin composition including such a cyanate ester compound more easily absorbs moisture in the atmosphere. Accordingly, the absorbed moisture evaporates during reflow operation, thereby likely forming voids in the insulation layer. Additionally, an epoxy compound has excellent curability but causes a reduced crosslink density and insufficient curing when the epoxy compound is included excessively, thereby aggravating dynamic characteristics of the cured product to be obtained and causing reduced heat resistance. Further, a peel strength of metal foil (e.g., copper foil peel strength) when incorporated into a metal foil-clad laminate is insufficient. Furthermore, when many epoxy groups remain in the cured product, they increases water absorption to easily cause a rise in dissipation factor of the entire cured product.

On the other hand, according to the resin composition of the present embodiment containing the cyanate ester compound and the epoxy compound in a specific functional group equivalent ratio, the reaction of the cyanate ester compound with the epoxy compound comparatively readily proceeds, thereby suitably inhibiting the hydrolysis of the cyanate ester compound by the dielectric powder and obtaining a cured product having low water absorption and excellent heat resistance. For this reason, voids are less likely formed in the insulation layer even during reflow operation. Additionally, since the resin composition contains the cyanate ester compound and the epoxy compound, a reduced crosslink density and insufficient curing are less likely caused to obtains suitable dynamic characteristics, and further the resin composition forms a triazine ring and an oxazoline ring in the cured product, whereby the insulation layer has a high glass transition temperature, a high peel strength of the metal foil, and a low coefficient of thermal expansion. Furthermore, the remaining amount of the epoxy group in the obtained cured product is smaller, thereby resulting in lower water absorption and less likely causing a rise in dissipation factor. In addition, the dielectric powder has a high permittivity even in the resin composition, such as a resin varnish, containing the cyanate ester compound and the epoxy compound. Thus, it is inferred that the resin composition according to the present embodiment can form a cured product and an insulation layer having a high permittivity and a low dissipation factor, low water absorption, favorable thermal characteristics, a high glass transition temperature, a high peel strength of the metal foil, and a low coefficient of thermal expansion.

### <Functional Group Equivalent Ratio>

Next, the functional group equivalent ratio will be described.

In the resin composition of the present embodiment, the functional group equivalent ratio of the cyanate group of the cyanate ester compound (B) to the epoxy group of the epoxy compound (C) (cyanate group/epoxy group) is 0.1 to 2.0. When the functional group equivalent ratio is within the above range, it is possible to simultaneously achieve a high permittivity and a low dissipation factor, low water absorption, favorable thermal characteristics, a high glass transition temperature, a high peel strength of the metal foil, and a low coefficient of thermal expansion. In view of obtaining a higher permittivity and a lower dissipation factor, lower water absorption, more favorable thermal characteristics, a higher glass transition temperature, a higher peel strength of the metal foil, and a lower coefficient of thermal expansion, the functional group equivalent ratio is preferably 0.2 to 1.8, more preferably 0.5 to 1.5, and further preferably 0.6 to 1.4. If a functional group equivalent ratio is less than 0.1, a content of epoxy compound (C) in the resin composition is higher, thereby aggravating dynamic characteristics of the cured product to be obtained and tending to cause reduced heat resistance. Additionally, a reduced crosslink density and insufficient curing are caused, and accordingly, a peel strength of metal foil (e.g., copper foil peel strength) when incorporated into a metal foil-clad laminate tends to be insufficient. Further, since many epoxy groups remain in the cured product, water absorption is higher, thereby tending to cause a rise in the dissipation factor of the entire cured product. On the other hand, if a functional group equivalent ratio is more than 2.0, a content of cyanate ester compound (B) in the resin composition is higher, and the dielectric powder and the cyanate ester compound form many complexes, thereby allowing the cyanate ester compound to be easily hydrolyzed. For this reason, it is inferred that the cured product to be obtained more easily absorbs moisture in the atmosphere, and the absorbed moisture evaporates during reflow operation, thereby tending to form voids in the insulation layer.

In the present embodiments, the functional group equivalent ratio refers to the ratio of an equivalent of the cyanate group in cyanate ester compound (B) included in the resin composition to an equivalent of the epoxy group in epoxy compound (C) included in the resin composition, and is calculated by the following formula (i). In the present embodiment, it is possible to use two or more compounds for either or both of cyanate ester compound (B) and epoxy compound (C). In such a case, the calculation method of the functional group equivalent ratio is follows; the number of functional groups in each component of cyanate ester compound (B) and epoxy compound (C) (that is, the equivalent of the cyanate group and the equivalent of the epoxy group) is calculated, and these values are totaled for cyanate ester compound (B) and those for epoxy compound (C), respectively, thereby calculating the equivalent of all the cyanate groups and the equivalent of all the epoxy groups. The functional group equivalent ratio is the value obtained by dividing the equivalent of all the cyanate groups by the equivalent of all the epoxy groups. The number of functional groups is the value obtained by dividing the amount in parts by mass of a component by the functional group equivalent of the component.

Functional group equivalent ratio=(amount in parts by mass of cyanate ester compound (B) in resin composition/functional group equivalent of cyanate ester compound (B))/(amount in parts by mass of epoxy compound (C) in resin composition/functional group equivalent of epoxy compound (C)) Formula (i):

Next, each component included in the resin composition will be described in detail.

### <Dielectric Powder (A)>

The resin composition of the present embodiment contains dielectric powder (A). For dielectric powder (A), dielectric powders can be used singly, or two or more thereof can also be used in combination.

The shape of dielectric powder (A) is not particularly limited, and examples include scale-like shapes, spherical shapes, plate-like shapes, and amorphous shapes. The shape of dielectric powder (A) is preferably spherical shape in view of being more compatible with cyanate ester compound (B) and epoxy compound (C), and obtaining the cured product having more favorable thermal characteristics, a high glass transition temperature, a low coefficient of thermal expansion, low water absorption, and more favorable dielectric characteristics (high permittivity and low dissipation factor), and further obtaining the insulation layer having a more favorable peel strength of the metal foil, and a further suitable surface hardness.

The relative permittivity of dielectric powder (A) is preferably 20 or more, and more preferably 25 or more. When a relative permittivity is 20 or more, the insulation layer having a high relative permittivity tends to be obtained. In the present embodiment, the relative permittivity of dielectric powder (A) is the value at 10 GHz measured by the cavity resonator method. In the present embodiment, the relative permittivity of dielectric powder (A) can be calculated using the Bruggeman formula (law of mixture). A specific measurement method can be referred to Examples.

The dissipation factor of dielectric powder (A) is preferably 0.015 or less, and more preferably 0.010 or less, and further preferably 0.008 or less. When a dissipation factor is 0.015 or less, the insulation layer having a low dissipation factor tends to be obtained. In the present embodiment, the dissipation factor of dielectric powder (A) is the value at 10 GHz measured by the cavity resonator method. In the present embodiment, the dissipation factor of dielectric powder (A) can be calculated using the Bruggeman formula (law of mixture). A specific measurement method can be referred to Examples.

The median particle size (D50) of dielectric powder (A) is preferably 0.1 to 5 μm, and more preferably 0.15 to 3 μm, in view of the dispersibility. In the present embodiment, the median particle size (D50) means the value at which a cumulative volume from smaller particles reaches 50% of the entire volume when a particle size distribution of a predetermined amount of a powder fed in a dispersion medium is measured using a laser diffraction scattering type particle size distribution analyzer. The median particle size (D50) can be calculated by measuring particle size distribution by a laser diffraction scattering method, but a specific measurement method can be referred to examples.

Examples of dielectric powder (A) include titanium oxide (TiO), barium titanate (BaTio₃), calcium titanate (CaTiO₃), strontium titanate (SrTiO₃), dititanium trioxide (Ti₂O₃), and titanium dioxide (TiO₂). Of these, dielectric powder (A) preferably contains one or more selected from the group consisting of titanium dioxide, barium titanate, calcium titanate, and strontium titanate, and is more preferably strontium titanate, in view of being more compatible with cyanate ester compound (B) and epoxy compound (C), and obtaining the cured product having more favorable thermal characteristics, a high glass transition temperature, a low coefficient of thermal expansion, low water absorption, and more favorable dielectric characteristics (high permittivity and low dissipation factor). Additionally, titanate oxide, dititanium trioxide, and titanium dioxide have a high relative permittivity and a suitable dissipation factor, and are thus preferable as dielectric powder (A).

For strontium titanate, a known compound can be used, and examples include oxides of a Perovskite structure mostly represented by ABO₃. Strontium titanate can contain a compound having a structure represented by (SrO)ₓ·TiO₂ (0.9≤X<1.0, 1.0<X≤1.1). In this compound, a part of Sr can be substituted with other metal elements, and examples of such a metal element include at least one of La (lanthanum), Ba (barium), and Ca (calcium). Also, in this compound, a part of Ti can be substituted with other metal elements, and examples of such a metal element include Zr (zirconium).

For titanium dioxide, those having rutile-type or anatase-type crystal structure are preferable, and those having rutile-type crystal structure are more preferable.

Dielectric powder (A) can be a commercial product. Examples of the commercial product include, as titanium dioxide, STT-30A and EC-300 manufactured by Titan Kogyo, Ltd., AEROXIDE (registered trademark, the same applies hereinafter) TiO₂ T805, AEROXIDE TiO₂ NKT90 (these are all product names) manufactured by NIPPON AEROSIL CO., LTD.; as barium titanate, 208108 (product name) manufactured by ALDRICH; as calcium titanate, CT series manufactured by Fuji Titanium Industry Co., Ltd.; as strontium titanate, ST-2 manufactured by KCM Corporation, ST-03 manufactured by SAKAI CHEMICAL INDUSTRY CO., LTD., 396141 manufactured by ALDRICH, ST, HST-1, HPST-1, and HPST-2 manufactured by Fuji Titanium Industry Co., Ltd., SW-100, SW-50C, SW-100C, SW-200C, SW-320C, and SW-350 (these are all product names) manufactured by Titan Kogyo, Ltd.; as dititanium trioxide, STR-100A-LP manufactured by SAKAI CHEMICAL INDUSTRY CO., LTD., and MT-N1 (these are all product names) manufactured by TAYCA CORPORATION.

The content of dielectric powder (A) is preferably 50 to 500 parts by mass, preferably 60 to 450 parts by mass, and more preferably 70 to 400 parts by mass, based on 100 parts by mass of the total of cyanate ester compound (B) and epoxy compound (C). When a content of dielectric powder (A) is within the above range, dielectric powder (A) is even more compatible with cyanate ester compound (B) and epoxy compound (C), and there is a tendency that it is possible to obtain the cured product having even more favorable thermal characteristics, a high glass transition temperature, a low coefficient of thermal expansion, low water absorption, and even more favorable dielectric characteristics (high permittivity and low dissipation factor) and further the insulation layer having an even more favorable peel strength of the metal foil, and a further suitable surface hardness.

The content of dielectric powder (A) is preferably 50 to 500 parts by mass, preferably 60 to 450 parts by mass, and more preferably 70 to 400 parts by mass, based on 100 parts by mass of the total resin solid content in the resin composition. When a content of dielectric powder (A) is within the above range, dielectric powder (A) is even more compatible with cyanate ester compound (B) and epoxy compound (C), and there is a tendency that it is possible to obtain the cured product having even more favorable thermal characteristics, a high glass transition temperature, a low coefficient of thermal expansion, low water absorption, and even more favorable dielectric characteristics (high permittivity and low dissipation factor) and further the insulation layer having an even more favorable peel strength of the metal foil, and a further suitable surface hardness.

### <Cyanate Ester Compound (B)>

The resin composition of the present embodiment contains cyanate ester compound (B). Since the resin composition contains cyanate ester compound (B) and epoxy compound (C) in a specific functional group equivalent ratio and contains dielectric powder (A), it is possible to obtain the cured product having a high permittivity and a low dissipation factor, low water absorption, favorable thermal characteristics, a high glass transition temperature, a high peel strength of the metal foil, and a low coefficient of thermal expansion, and suitable for an insulation layer of a printed wiring board.

For cyanate ester compound (B), cyanate ester compounds can be used singly, or two or more thereof can also be used in combination.

Cyanate ester compound (B) is not particularly limited as long as the compound has two or more cyanate groups directly bonding an aromatic ring in the molecule (also referred to as “cyanate ester group”, or “cyanate group”). Examples of such a cyanate ester compound (B) include naphthol aralkyl-type cyanate ester compounds, phenol novolac-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, and biphenyl aralkyl-type cyanate ester compounds, bis(3,3-dimethyl-4-cyanatephenyl) methane, bis(4-cyanatephenyl) methane, 1,3-dicyanatebenzene, 1,4-dicyanatebenzene, 1,3,5-tricyanatebenzene, 1,3-dicyanatenaphthalene, 1,4-dicyanatenaphthalene, 1,6-dicyanatenaphthalene, 1,8-dicyanatenaphthalene, 2,6-dicyanatenaphthalene, 2,7-dicyanatenaphthalene, 1,3,6-tricyanatenaphthalene, 4,4′-dicyanatebiphenyl, bis(4-cyanatephenyl) ether, bis(4-cyanatephenyl)thioether, bis(4-cyanatephenyl) sulfone, and 2,2-bis(4-cyanatephenyl)propane. Of these, cyanate ester compound (B) preferably contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, and biphenyl aralkyl-type cyanate ester compounds.

Cyanate ester compound (B) is more preferably naphthol aralkyl-type cyanate ester compounds, and further preferably the compound represented by a formula (1), in view of being more compatible with dielectric powder (A), obtaining the cured product having further favorable thermal characteristics, a high glass transition temperature, a low coefficient of thermal expansion, low water absorption, and further favorable dielectric characteristics (high permittivity and low dissipation factor, particularly, a much higher permittivity), and obtaining the insulation layer having an even more favorable peel strength of the metal foil, and a more suitable surface hardness.

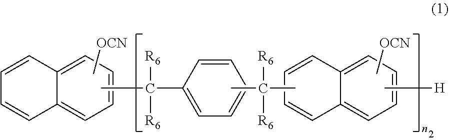

In the formula (1), R₆ each independently represents a hydrogen atom or a methyl group, and n₂ represents an integer of 1 or more. n₂ is preferably an integer of 1 to 20, more preferably an integer of 1 to 10, and further preferably an integer of 1 to 6.

These cyanate ester compounds (B) can be produced in accordance with a known method. Examples of the specific production method include a method described in Japanese Patent Laid-Open No. 2017-195334 (particularly, paragraphs from 0052 to 0057).

The content of cyanate ester compound (B) is 1 to 99 parts by mass, preferably 5 to 80 parts by mass, and more preferably 10 to 70 parts by mass, based on 100 parts by mass of the total of cyanate ester compound (B) and epoxy compound (C). When a content of cyanate ester compound (B) is within the above range, cyanate ester compound (B) is more compatible with dielectric powder (A), and there is a tendency that it is possible to obtain the cured product having more favorable thermal characteristics, a high glass transition temperature, a low coefficient of thermal expansion, low water absorption, and more favorable dielectric characteristics (high permittivity and low dissipation factor), and the insulation layer having a more favorable peel strength of the metal foil, and a more suitable surface hardness.

The content of cyanate ester compound (B) is preferably 1 to 99 parts by mass, preferably 5 to 80 parts by mass, and more preferably 10 to 70 parts by mass, based on 100 parts by mass of the total resin solid content in the resin composition. When a content of cyanate ester compound (B) is within the above range, cyanate ester compound (B) is more compatible with dielectric powder (A), and there is a tendency that it is possible to obtain the cured product having more favorable thermal characteristics, a high glass transition temperature, a low coefficient of thermal expansion, low water absorption, and more favorable dielectric characteristics (high permittivity and low dissipation factor), and the insulation layer having a more favorable peel strength of the metal foil, and a more suitable surface hardness.

### <Epoxy Compound (C)>

The resin composition of the present embodiment contains epoxy compound (C). Since the resin composition contains cyanate ester compound (B) and epoxy compound (C) in a specific functional group equivalent ratio and contains dielectric powder (A), it is possible to obtain the cured product having a high permittivity and a low dissipation factor, low water absorption, favorable thermal characteristics, a high glass transition temperature, a high peel strength of the metal foil, and a low coefficient of thermal expansion, and suitable for an insulation layer of a printed wiring board.

For epoxy compound (C), a known compound can be appropriately used as long as the compound or resin has one or more epoxy groups in a molecule, and the kind thereof is not particularly limited. The number of epoxy groups based on a molecule of epoxy compound (C) is one or more, and preferably two or more. The epoxy compounds can be used singly, or two or more thereof can also be used in combination.

For epoxy compound (C), conventionally known epoxy compounds and epoxy resins can be used. Examples include biphenyl aralkyl-type epoxy resins, naphthalene-type epoxy resins, bisnaphthalene-type epoxy resins, polyfunctional phenol-type epoxy resins, naphthylene ether-type epoxy resins, phenol aralkyl-type epoxy resins, phenol novolac-type epoxy resins, cresol novolac-type epoxy resins, xylene novolac-type epoxy resins, naphthalene backbone-modified novolac-type epoxy resins, dicyclopentadiene novolac-type epoxy resins, biphenyl novolac-type epoxy resins, phenol aralkyl novolac-type epoxy resins, naphthol aralkyl novolac-type epoxy resins, aralkyl novolac-type epoxy resins, aromatic hydrocarbon formaldehyde-type epoxy compounds, anthraquinone-type epoxy compounds, anthracene-type epoxy resins, naphthol aralkyl-type epoxy compounds, dicyclopentadiene-type epoxy resins, ZYLOCK-type epoxy compounds, bisphenol A-type epoxy resins, bisphenol E-type epoxy resins, bisphenol F-type epoxy resins, bisphenol S-type epoxy resins, bisphenol A novolac-type epoxy resins, phenol-type epoxy compounds, biphenyl-type epoxy resins, aralkyl novolac-type epoxy resins, triazine backbone epoxy compounds, triglycidyl isocyanurate, alicyclic epoxy resins, polyol-type epoxy resins, glycidylamine, glycidyl-type ester resins, compounds obtained by epoxidating a double bond of a double bond-containing compound such as butadiene, such as butadiene backbone-containing epoxy resins, and compounds obtained by reaction of hydroxy group-containing silicone resins and epichlorohydrin.

Of these, epoxy compound (C) preferably contains one or more selected from the group consisting of biphenyl aralkyl-type epoxy resins, naphthalene-type epoxy resins, naphthylene ether-type epoxy resins, and butadiene backbone-containing epoxy resins, and more preferably contains one or more selected from the group consisting of biphenyl aralkyl-type epoxy resins, naphthalene-type epoxy resins, and naphthylene ether-type epoxy resins, in view of being more compatible with dielectric powder (A), and obtaining the cured product having more favorable thermal characteristics, a high glass transition temperature, a low coefficient of thermal expansion, low water absorption, and more favorable dielectric characteristics (high permittivity and low dissipation factor), and obtaining the insulation layer having an even more favorable peel strength of the metal foil, and a more suitable surface hardness. Additionally, since these epoxy compounds are more compatible with and react to cyanate ester compound (B), there is a tendency that it is possible to obtain the cured product having more favorable thermal characteristics, a high glass transition temperature, a low coefficient of thermal expansion, low water absorption, and more favorable dielectric characteristics (high permittivity and low dissipation factor, particularly, a much higher permittivity), and the insulation layer having an even more favorable peel strength of the metal foil, and a more suitable surface hardness. Further, cyanate ester compound (B) to be used in combination with these epoxy compounds is preferably naphthol aralkyl-type cyanate ester compounds, and more preferably the compound represented by the formula (1) because of having a stiff backbone, and particularly favorable heat resistance and dissipation factor.

The biphenyl aralkyl-type epoxy resins are preferably compounds represented by the following formula (2).

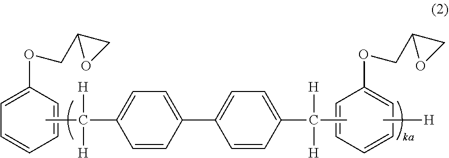

In the formula (2), ka represents an integer of 1 or more, is preferably 1 to 20, and more preferably 1 to 10.

Biphenyl aralkyl-type epoxy resins can be a commercial product, or a product produced by a known method can also be used. Examples of the commercial products include “NC-3000”, “NC-3000L”, “NC-3000H”, and “NC-3000FH”, the products manufactured by Nippon Kayaku Co., Ltd. (NC-3000FH is the compound represented by the above formula (2), and in the formula (2), ka is an integer of 1 to 10).

Naphthalene-type epoxy resins are preferably the compound represented by the following formula (3).

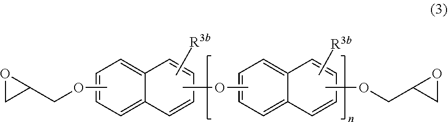

In the formula (3), R^{3b} each independently represents a hydrogen atom, an alkyl group having 1 to 5 carbon atoms (e.g., a methyl group or an ethyl group), an aralkyl group, a benzyl group, a naphthyl group, a naphthyl group containing at least one glycidyloxy group, or a naphthylmethyl group containing at least one glycidyloxy group, and n represents an integer of 0 or more (e.g., 0 to 2).

Examples of the commercial products of the compounds represented by the above formula (3) include “EPICLON (registered trademark) EXA-4032-70M” (EXA-4032-70M has, in the above formula (3), n=0, and R^{3b} being all hydrogen atoms), and “EPICLON (registered trademark) HP-4710” (in the above formula (3), n=0, and R^{3b} is a naphthylmethyl group containing at least one glycidyloxy group), which are the products manufactured by DIC corporation.

Naphthylene ether-type epoxy resins are preferably the bifunctional epoxy compound represented by the following formula (4) or the polyfunctional epoxy compound represented by the following formula (5), or a mixture thereof.

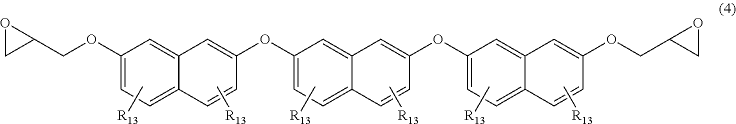

In the formula (4), R₁₃ each independently represents a hydrogen atom, an alkyl group having 1 to 3 carbon atoms (e.g., a methyl group or an ethyl group), or an alkenyl group having 2 to 3 carbon atoms (e.g., a vinyl group, an allyl group, or a propenyl group).

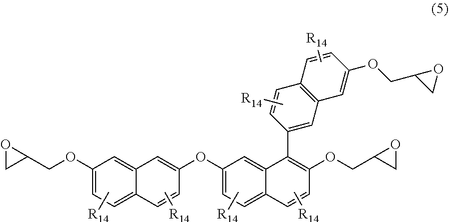

In the formula (5), R₁₄ each independently represents a hydrogen atom, an alkyl group having 1 to 3 carbon atoms (e.g., a methyl group or an ethyl group), or an alkenyl group having 2 to 3 carbon atoms (e.g., a vinyl group, an allyl group, or a propenyl group).

Naphthylene ether-type epoxy resins can be a commercial product, or a product produced by a known method can also be used. Examples of the commercial products include “HP-6000”, “EXA-7300”, “EXA-7310”, “EXA-7311”, “EXA-7311L”, “EXA7311-G3”, “EXA7311-G4”, “EXA-7311G4S”, and “EXA-7311G5”, the products manufactured by DIC corporation, and of which, “HP-6000” is preferable.

Butadiene backbone-containing epoxy resins can be any epoxy resins as long as the resin has the butadiene backbone and an epoxy group in a molecule. Examples of the resin include the butadiene backbone-containing epoxy resins represented by the following formulae (6) to (8).

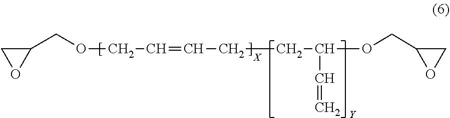

In the formula (6), X represents an integer of 1 to 100, and Y represents an integer of 0 to 100.

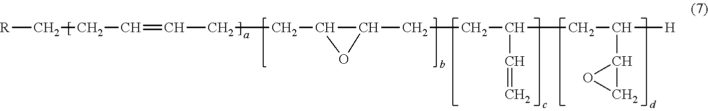

In the formula (7), R represents a hydrogen atom or an alkyl group having 1 to 10 carbon atoms, a and b each independently represent an integer of 1 to 100, c and d each independently represent an integer of 0 to 100. Examples of the alkyl group include a methyl group, an ethyl group, a propyl group, and a butyl group.

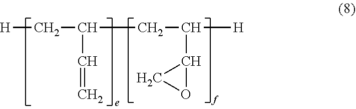

In the formula (8), e represents an integer of 24 to 35, and f represents an integer of 8 to 11.

Butadiene backbone-containing epoxy resins can be a commercial product, or a product produced by a known method can also be used. Examples of the commercial products include “R-15EPT” and “R-45EPT” (R-45EPT is the compound having, in the above formula (6), X=50 and Y=0) the products manufactured by Nagase Chemtex Corporation, “EPOLEAD (registered trademark) PB3600” and “PB4700”, the products manufactured by Daicel Corporation, and “Nisseki polybutadiene E-1000-3.5”, the product manufactured by Nippon Petrochemicals Co., Ltd.

The content of epoxy compound (C) is 1 to 99 parts by mass, preferably 20 to 95 parts by mass, and more preferably 30 to 90 parts by mass, based on 100 parts by mass of the total of cyanate ester compound (B) and epoxy compound (C). When a content of epoxy compound (C) is within the above range, epoxy compound (C) is more compatible with dielectric powder (A), and there is a tendency that it is possible to obtain the cured product having more favorable thermal characteristics, a high glass transition temperature, a low coefficient of thermal expansion, low water absorption, and more favorable dielectric characteristics (high permittivity and low dissipation factor), and the insulation layer having a more favorable peel strength of the metal foil, and a more suitable surface hardness.

The content of epoxy compound (C) is preferably 1 to 99 parts by mass, preferably 20 to 95 parts by mass, and more preferably 30 to 90 parts by mass, based on 100 parts by mass of the total resin solid content in the resin composition. When a content of epoxy compound (C) is within the above range, epoxy compound (C) is more compatible with dielectric powder (A), there is a tendency that it is possible to obtain the cured product having more favorable thermal characteristics, a high glass transition temperature, a low coefficient of thermal expansion, low water absorption, and more favorable dielectric characteristics (high permittivity and low dissipation factor), and the insulation layer having a more favorable peel strength of the metal foil, and a more suitable surface hardness.

### <Thermosetting Resin or Compound>

The resin composition of the present embodiment can further contain a thermosetting resin or compound which is different from cyanate ester compound (B) and epoxy compound (C) (hereinafter, referred to as the “thermosetting resin”), as long as the effects of the present invention are exhibited.

Examples of the thermosetting resin include one or more thermosetting resins or compounds selected from the group consisting of maleimide compounds, modified polyphenylene ether compounds, phenolic compounds, alkenyl-substituted nadiimide compounds, oxetane resins, benzoxazine compounds, and compounds having a polymerizable unsaturated group, in view of allowing dielectric powder (A), cyanate ester compound (B), and epoxy compound (C) to be even more compatible, obtaining the cured product having more favorable thermal characteristics, a high glass transition temperature, a low coefficient of thermal expansion, low water absorption, and more favorable dielectric characteristics (high permittivity and low dissipation factor), and obtaining the insulation layer having a favorable peel strength of the metal foil, and a more suitable surface hardness. The thermosetting resins can be used singly, or two or more thereof can also be used in combination.

The thermosetting resin preferably contains one or more selected from the group consisting of maleimide compounds, modified polyphenylene ether compounds, phenolic compounds, and compounds having a polymerizable unsaturated group, in view of allowing dielectric powder (A), cyanate ester compound (B), and epoxy compound (C) to be even more compatible, obtaining the cured product having even more favorable thermal characteristics, a high glass transition temperature, a low coefficient of thermal expansion, low water absorption, and more favorable dielectric characteristics (high permittivity and low dissipation factor), and obtaining the insulation layer having an even more favorable peel strength of the metal foil, and an even more suitable surface hardness.

The content of the thermosetting resin is preferably, in total, 10 to 150 parts by mass, more preferably 20 to 120 parts by mass, and further preferably 30 to 100 parts by mass, based on 100 parts by mass of the total of cyanate ester compound (B) and epoxy compound (C), in view of allowing dielectric powder (A), cyanate ester compound (B), and epoxy compound (C) to be even more compatible, obtaining the cured product having even more favorable thermal characteristics, a high glass transition temperature, a low coefficient of thermal expansion, low water absorption, and even more favorable dielectric characteristics (high permittivity and low dissipation factor), and obtaining the insulation layer having an even more favorable peel strength of the metal foil, and an even more suitable surface hardness.

When the resin composition further contains the thermosetting resin, the total content of cyanate ester compound (B) and epoxy compound (C), in terms of the lower limit value thereof, can be 20 parts by mass or more, is preferably 30 parts by mass or more, more preferably 40 parts by mass or more, and further preferably 50 parts by mass or more, based on 100 parts by mass of the total resin solid content in the resin composition, in view of easily exhibiting the effects of the present invention. For the upper limit value, the content can be 100 parts by mass or less, is preferably 90 parts by mass or less, more preferably 85 parts by mass or less, and further preferably 80 parts by mass or less, in view of easily exhibiting the effects of the present invention.

### (Maleimide Compound)

The resin composition of the present embodiment can contain a maleimide compound.

For the maleimide compound, a known compound can be appropriately used as long as the compound has one or more maleimide groups in a molecule, and the kind thereof is not particularly limited. The number of maleimide groups in a molecule of the maleimide compound is one or more, and preferably two or more. The maleimide compounds can be used singly, or two or more thereof can also be used in combination.

Examples of the maleimide compound include N-phenylmaleimide, N-hydroxyphenylmaleimide, bis(4-maleimidephenyl)methane, 2,2-bis(4-(4-maleimidephenoxy)-phenyl)propane, bis(3,5-dimethyl-4-maleimidephenyl)methane, bis(3-ethyl-5-methyl-4-maleimidephenyl)methane, bis(3,5-diethyl-4-maleimidephenyl)methane, maleimide compounds represented by a formula (9), and maleimide compounds represented by a formula (10), maleimide compounds represented by a formula (11), prepolymers of these maleimide compounds, and prepolymers of the above maleimide compound and an amine compound.

Of these, the maleimide compound preferably contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the formula (9), maleimide compounds represented by the formula (10), and maleimide compounds represented by the formula (11), in view of allowing dielectric powder (A), cyanate ester compound (B), and epoxy compound (C) to be even more compatible, obtaining the cured product having even more favorable thermal characteristics, a high glass transition temperature, a low coefficient of thermal expansion, low water absorption, and even more favorable dielectric characteristics (high permittivity and low dissipation factor), and obtaining the insulation layer having an even more favorable peel strength of the metal foil, and a further more suitable surface hardness.

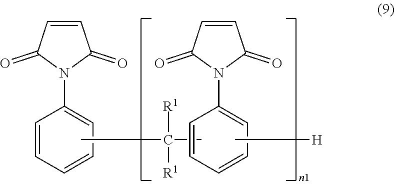

In the formula (9), R¹ each independently represents a hydrogen atom or a methyl group, n1 is an integer of 1 to 10.

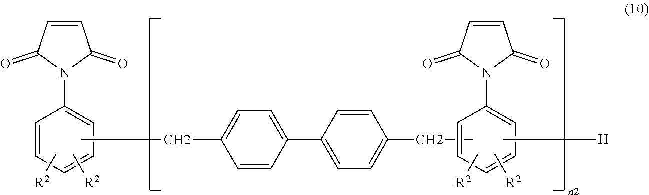

In the formula (10), R² each independently represents a hydrogen atom, an alkyl group having 1 to 5 carbon atoms, or a phenyl group, n2 is an average value and represents 1<n2≤5.

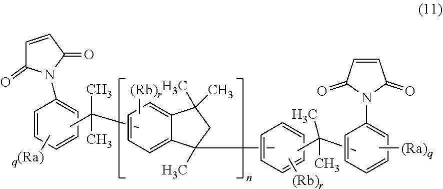

In the formula (11), Ra each independently represents a hydrogen atom, an alkyl group, an alkyloxy group, or an alkylthio group, each having 1 to 10 carbon atoms, an aryl group, an aryloxy group, or an arylthio group each having 6 to 10 carbon atoms, a cycloalkyl group having 3 to 10 carbon atoms, a halogen atom, a nitro group, a hydroxy group, or a mercapto group; q represents an integer of 0 to 4, and when q is an integer of 2 to 4, Ra can be the same or different in the same ring; Rb each independently represents a hydrogen atom, an alkyl group, an alkyloxy group, or an alkylthio group, each having 1 to 10 carbon atoms, an aryl group, an aryloxy group, or an arylthio group, each having 6 to 10 carbon atoms, a cycloalkyl group having 3 to 10 carbon atoms, a halogen atom, a hydroxy group, or a mercapto group; r represents an integer of 0 to 3, and when r is 2 or 3, Rb can be the same or different in the same ring; and n is the average number of repeat units and represents a value of 0.95 to 10.0.

In the formula (11), Ra each independently is preferably a hydrogen atom, an alkyl group having 1 to 6 carbon atoms, a cycloalkyl group having 3 to 6 carbon atoms, or an aryl group having 6 to 10 carbon atoms, and more preferably an alkyl group having 1 to 3 carbon atoms.

In the formula (11), q is preferably 2 or 3, and more preferably 2.

In the formula (11), all Rb are preferably a hydrogen atom. It is also preferable that, when r is an integer of 1 to 3, Rb each independently be a hydrogen atom, an alkyl group having 1 to 6 carbon atoms, a cycloalkyl group having 3 to 6 carbon atoms, or an aryl group having 6 to 10 carbon atoms.

The content of maleimide compound is preferably 10 to 80 parts by mass, more preferably 15 to 70 parts by mass, and further preferably 20 to 60 parts by mass, based on 100 parts by mass of the total of cyanate ester compound (B) and epoxy compound (C). When a content of the maleimide compound is within the above range, dielectric powder (A), cyanate ester compound (B) and epoxy compound (C) are more compatible, and there is a tendency that it is possible to obtain the cured product having still more favorable thermal characteristics, a high glass transition temperature, a low coefficient of thermal expansion, low water absorption, and more favorable dielectric characteristics (high permittivity and low dissipation factor), and the insulation layer having a still more favorable peel strength of the metal foil, and a still more suitable surface hardness.

The content of the maleimide compound is preferably 10 to 80 parts by mass, more preferably 15 to 70 parts by mass, and further preferably 20 to 60 parts by mass, based on 100 parts by mass of the total resin solid content in the resin composition. When a content of the maleimide compound is within the above range, dielectric powder (A), cyanate ester compound (B) and epoxy compound (C) are still more compatible, and there is a tendency that it is possible to obtain the cured product having still more favorable thermal characteristics, a high glass transition temperature, a low coefficient of thermal expansion, low water absorption, and more favorable dielectric characteristics (high permittivity and low dissipation factor), and the insulation layer having a still more favorable peel strength of the metal foil, and a still more suitable surface hardness.

Maleimide compounds can be a commercial product, or a product produced by a known method can also be used. Examples of the commercial product of the maleimide compound include “BMI-70”, “BMI-80”, and “BMI-1000P”, the products manufactured by K. I Chemical Industry Co., Ltd., “BMI-3000”, “BMI-4000”, “BMI-5100”, “BMI-7000”, and “BMI-2300” (the maleimide compounds represented by the above formula (9)), the products manufactured by Daiwa Kasei Industry Co., Ltd., “MIR-3000-MT” (the maleimide compound represented by the above formula (10)), the product manufactured by Nippon Kayaku Co., Ltd., and “NE-X-9470S” (the maleimide compound represented by the above formula (11)), the product manufactured by DIC corporation.

### (Modified Polyphenylene Ether Compound)

The resin composition of the present embodiment can contain a modified polyphenylene ether compound.

For the modified polyphenylene ether compound, a known compound can be appropriately used and is not particularly limited as long as the polyphenylene ether compound is modified at a part or all of the terminals thereof. The modified polyphenylene ether compounds can be used singly, or two or more thereof can also be used in combination.

Examples of the polyphenylene ether compound for the modified polyphenylene ether compound include polymers including at least one structural unit selected from the structural units represented by a formula (12), the structural units represented by a formula (13), and the structural units represented by a formula (14).

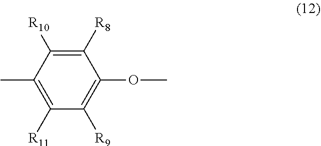

In the formula (12), R₈, R₉, R₁₀, and R₁₁ each independently represent an alkyl group having 6 or less carbon atoms, an aryl group, a halogen atom, or a hydrogen atom.

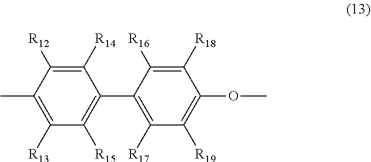

In the formula (13), R₁₂, R₁₃, R₁₄, R₁₈, and R₁₉ each independently represent an alkyl group having 6 or less carbon atoms or a phenyl group. R₁₅, R₁₆, and R₁₇ each independently represent a hydrogen atom, an alkyl group having 6 or less carbon atoms or a phenyl group.

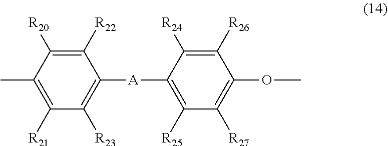

In the formula (14), R₂₀, R₂₁, R₂₂, R₂₃, R₂₄, R₂₅, R₂₆, and R₂₇ each independently represent a hydrogen atom, an alkyl group having 6 or less carbon atoms, or a phenyl group. -A- is a straight-, branched-, or cyclic-chain divalent hydrocarbon group having 20 or less carbon atoms.

In the formula (14), examples of the -A- include, but not limited to, divalent organic groups such as a methylene group, an ethylidene group, a 1-methylethylidene group, a 1,1-propylidene group, a 1,4-phenylenebis(1-methylethylidene) group, a 1,3-phenylenebis(1-methylethylidene) group, a cyclohexylidene group, a phenylmethylene group, a naphthylmethylene group, and a 1-phenylethylidene group.

The modified polyphenylene ether compound is preferably, for example, modified polyphenylene ether compounds having a functional group such as an ethylenically unsaturated group such as a vinyl benzyl group, an epoxy group, an amino group, a hydroxy group, a mercapto group, a carboxy group, a methacryl group, and a silyl group at a part or all of the terminals of a polyphenylene ether compound.

Examples of the modified polyphenylene ether compound whose terminal is a hydroxy group include SA90 (product name) manufactured by SABIC innovative plastics.

Examples of the modified polyphenylene ether compound whose terminal is a methacryl group include SA9000 (product name) manufactured by SABIC innovative plastics.

The production method of the modified polyphenylene ether compound is not particularly limited as long as the effects of the present invention can be obtained. For example, the modified polyphenylene ether compound can be produced by the method described in U.S. Pat. No. 4,591,665.

The modified polyphenylene ether compound can contain a modified polyphenylene ether compound having a terminal ethylenically unsaturated group. Examples of the ethylenically unsaturated group include alkenyl groups such as an ethenyl group, an allyl group, an acryl group, a methacryl group, a propenyl group, a butenyl group, a hexenyl group, and an octenyl group; cycloalkenyl groups such as cyclopentenyl group and a cyclohexenyl group; and alkenylaryl groups such as a viny benzyl group and a vinyl naphthyl group.

The terminal ethylenically unsaturated group can be one or more, and can be the same functional group or different functional groups.

In view of allowing dielectric powder (A), cyanate ester compound (B), and epoxy compound (C) to be even more compatible, obtaining the cured product having even more favorable thermal characteristics, a high glass transition temperature, a low coefficient of thermal expansion, low water absorption, and even more favorable dielectric characteristics (high permittivity and low dissipation factor), and obtaining the insulation layer having an even more favorable peel strength of the metal foil, and a more suitable surface hardness, the modified polyphenylene ether compound having a terminal ethylenically unsaturated group is preferably the compounds represented by a formula (15).

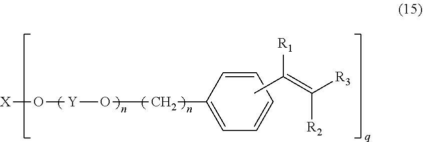

In the formula (15), X represents an aromatic group, and —(Y—O)ₘ— represents a polyphenylene ether moiety. R₁, R₂, and R₃ each independently represent a hydrogen atom, an alkyl group, an alkenyl group, or an alkynyl group, m represents an integer of 1 to 100, n represents an integer of 1 to 6, q represents an integer of 1 to 4. m is preferably an integer of 1 or more and 50 or less, and more preferably 1 or more and 30 or less. n is preferably an integer of 1 or more and 4 or less, more preferably 1 or 2, and ideally 1. q is preferably an integer of 1 or more and 3 or less, more preferably 1 or 2, and ideally 2.

Examples of the aromatic group represented by X in the formula (15) include groups formed by removing q hydrogen atoms from one ring structure selected from benzene ring structure, biphenyl ring structure, indenyl ring structure, and naphthalene ring structure (e.g., a phenylene group, a biphenylene group, indenylene group, and a naphthylene group).

The aromatic group represented by X herein can contain, for example, a group formed by bonding aryl groups via an oxygen atom, such as a diphenyl ether group, a group formed by bonding aryl groups via a carbonyl group, such as a benzophenone group, or a group formed by bonding aryl groups via an alkylene group, such as a 2,2-diphenylpropane group.

The aromatic group can be substituted with a general substituent such as an alkyl group (suitably an alkyl group having 1 to 6 carbon atoms, particularly a methyl group), an alkenyl group, an alkynyl group, and a halogen atom. However, the aromatic group is bonded to a polyphenylene ether moiety via an oxygen atom, and accordingly, the limit in the number of general substituents depends on the number of polyphenylene ether moieties.

For the polyphenylene ether moiety in the formula (15), the structural unit represented by the formula (12), the structural unit represented by the formula (13), and the structural unit represented by the formula (14) can be used.

Among the compounds represented by the formula (15), the modified polyphenylene ether compound is preferably the compound represented by the following formula (16).

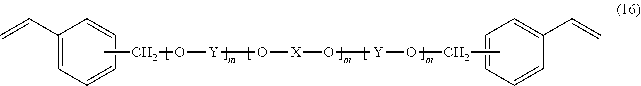

In the formula (16), X is an aromatic group, —(Y—O)ₘ— each independently represent a polyphenylene ether moiety, and m represents an integer of 1 to 100. m is preferably an integer of 1 or more and 50 or less, and more preferably an integer of 1 or more and 30 or less.

X, —(Y—O)ₘ—, and m in the formula (16) are the same as defined for in the formula (15).

X in the formula (15) and formula (16) is a formula (17), a formula (18), or a formula (19), and —(Y—O)ₘ— and —(O—Y)ₘ— in the formula (15) and the formula (16) are a structure in which a formula (20) or a formula (21) is arranged, or a structure in which the formula (20) and the formula (21) are arranged in block or randomly.

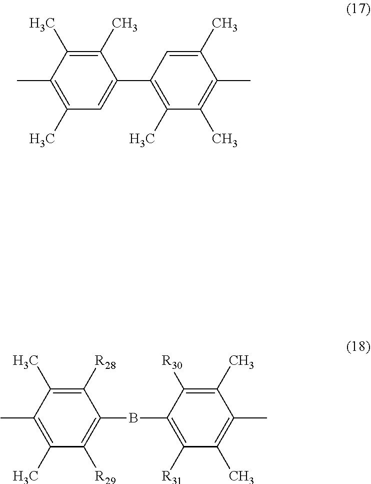

In the formula (18), R₂₈, R₂₉, R₃₀, and R₃₁ each independently represent a hydrogen atom or a methyl group. —B— is a straight-, branched-, or cyclic-chain divalent hydrocarbon group having 20 or less carbon atoms.

Specific examples of —B— include those that are the same as the specific examples of -A- in the formula (14).

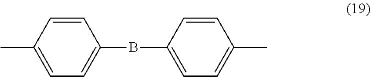

In the formula (19), —B— is a straight-, branched-, or cyclic-chain divalent hydrocarbon group having 20 or less carbon atoms.

Specific examples of —B— include those listed as the specific examples of -A- in the formula (14).

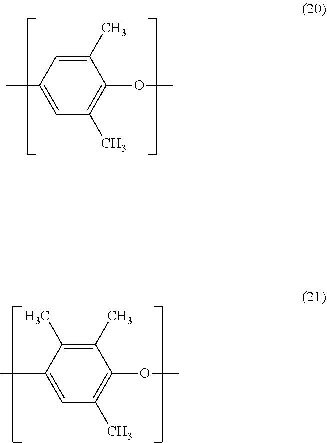

The production method of the modified polyphenylene ether compound having the structure represented by the formula (16) is not particularly limited, and, for example, such a modified polyphenylene ether compound can be produced by oxidatively coupling a bifunctional phenolic compound and a monofunctional phenolic compound to obtain a bifunctional phenylene ether oligomer, and vinylbenzyl-etherifying the terminal phenolic hydroxy group of the obtained bifunctional phenylene ether oligomer.

The modified polyphenylene ether compound can be a commercial product, and, for example, OPE-2St1200 and OPE-2st2200 manufactured by MITSUBISHI GAS CHEMICAL COMPANY, INC. can be suitably used.

The content of the modified polyphenylene ether compound is preferably 1 to 50 parts by mass based on 100 parts by mass of the total of cyanate ester compound (B) and epoxy compound (C).

The content of the modified polyphenylene ether compound is preferably 1 to 50 parts by mass based on 100 parts by mass of the total resin solid content in the resin composition.

### (Phenolic Compound)

The resin composition of the present embodiment can contain a phenolic compound.

For the phenolic compound, a known compound can be appropriately used as long as the compound has two or more phenolic hydroxy groups in one molecule, and the kind thereof is not particularly limited. The phenolic compounds can be used singly, or two or more thereof can also be used in combination.

Examples of the phenolic compound include cresol novolac-type phenolic resins, biphenyl aralkyl-type phenolic resins represented by the formula (22), naphthol aralkyl-type phenolic resins represented by the formula (23), aminotriazine novolac-type phenolic resins, naphthalene-type phenolic resins, phenol novolac resins, alkylphenol novolac resins, bisphenol A-type novolac resins, dicyclopentadiene-type phenolic resins, ZYLOCK-type phenolic resins, terpene-modified phenolic resins, and polyvinylphenols.

Of these, cresol novolac-type phenolic resins, biphenyl aralkyl-type phenolic resins represented by the formula (22), naphthol aralkyl-type phenolic resins represented by the formula (23), aminotriazine novolac-type phenolic resins, and naphthalene-type phenolic resins are preferable in view of obtaining excellent formability and surface hardness.

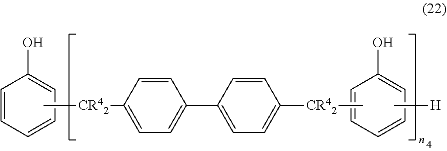

In the formula (22), R⁴ each independently represents a hydrogen atom or a methyl group, and n₄ is an integer of 1 to 10.

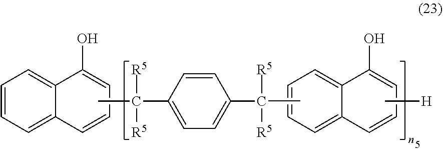

In the formula (23), R⁵ each independently represents a hydrogen atom or a methyl group, and n₅ is an integer of 1 to 10.

The content of the phenolic compound is preferably 1 to 50 parts by mass based on 100 parts by mass of the total of cyanate ester compound (B) and epoxy compound (C).

The content of the phenolic compound is preferably 1 to 50 parts by mass based on 100 parts by mass of the total resin solid content in the resin composition.

### (Alkenyl-Substituted Nadiimide Compound)

The resin composition of the present embodiment can contain an alkenyl-substituted nadiimide compounds.

The alkenyl-substituted nadiimide compound is not particularly limited as long as the compound has one or more alkenyl-substituted nadiimide groups in a molecule. The alkenyl-substituted nadiimide compounds can be used singly, or two or more thereof can also be used in combination.

Examples of the alkenyl-substituted nadiimide compound include the compound represented by the following formula (24).

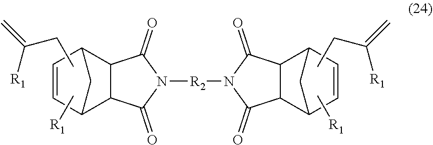

In the formula (24), R₁ each independently represents a hydrogen atom or an alkyl group having 1 to 6 carbon atoms (e.g., a methyl group or an ethyl group), R₂ represents an alkylene group having 1 to 6 carbon atoms, a phenylene group, a biphenylene group, a naphthylene group, or a group represented by a formula (25) or a formula (26).

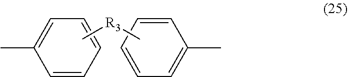

In the formula (25), Ra represents a methylene group, an isopropylidene group, CO, O, S, or SO₂.

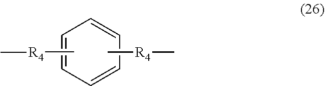

In the formula (26), R₄ each independently represents an alkylene having 1 to 4 carbon atoms, or a cycloalkylene group having 5 to 8 carbon atoms.

The alkenyl-substituted nadiimide compounds represented by the formula (24) can be a commercial product, or a product produced in accordance with a known method can also be used. Examples of the commercial product include “BANI-M” and “BANI-X”, the products manufactured by Maruzen Petrochemical Co., Ltd.

The content of the alkenyl-substituted nadiimide compound is preferably 1 to 50 parts by mass based on 100 parts by mass of the total of cyanate ester compound (B) and epoxy compound (C).

The content of the alkenyl-substituted nadiimide compound is preferably 1 to 50 parts by mass based on 100 parts by mass of the total resin solid content in the resin composition.

### (Oxetane Resin)

The resin composition of the present embodiment can contain an oxetane resin.

Oxetane resin is not particularly limited, and a generally known resin can be used. The oxetane resins can be used singly, or two or more thereof can also be used in combination.

Examples of the oxetane resin include alkyloxetane such as oxetane, 2-methyloxetane, 2,2-dimethyloxetane, 3-methyloxetane, and 3,3-dimethyloxetane, 3-methyl-3-methoxymethyloxetane, 3,3-di(trifluoromethyl) perfluorooxetane, 2-chloromethyloxetane, 3,3-bis(chloromethyl) oxetane, biphenyl-type oxetane, OXT-101 (product name, Toagosei Co., Ltd.), and OXT-121 (product name, Toagosei Co., Ltd.).

The content of the oxetane resin is preferably 1 to 50 parts by mass based on 100 parts by mass of the total of cyanate ester compound (B) and epoxy compound (C).

The content of the oxetane resin is preferably 1 to 50 parts by mass based on 100 parts by mass of the total of resin solid contents in the resin composition.

### (Benzoxazine Compound)

The resin composition of the present embodiment can contain a benzoxazine compound.

The benzoxazine compound is not particularly limited as long as the compound has two or more dihydrobenzoxazine rings in a molecule, and a generally known compound can be used. The benzoxazine compounds can be used singly, or two or more thereof can also be used in combination.

Examples of the benzoxazine compound include bisphenol A-type benzoxazine BA-BXZ (product names, Konishi Chemical Ind. Co., Ltd.), bisphenol F-type benzoxazine BF—BXZ (product names, Konishi Chemical Ind. Co., Ltd.), and bisphenol S-type benzoxazine BS—BXZ (product names, Konishi Chemical Ind. Co., Ltd.).

The content of the benzoxazine compound is preferably 1 to 50 parts by mass based on 100 parts by mass of the total of cyanate ester compound (B) and epoxy compound (C).

The content of the benzoxazine compound is preferably 1 to 50 parts by mass based on 100 parts by mass of the total of resin solid contents in the resin composition.

### (Compound Having a Polymerizable Unsaturated Group)

The resin composition of the present embodiment can contain a compound having a polymerizable unsaturated group.

The compound having a polymerizable unsaturated group is not particularly limited, and a generally known compound can be used. The compounds having a polymerizable unsaturated group can be used singly, or two or more thereof can also be used in combination.

Examples of the compound having a polymerizable unsaturated group include vinyl compounds such as ethylene, propylene, styrene, divinyl benzene, and divinyl biphenyl; meth(acrylates) of monohydric or polyhydric alcohol such as methyl (meth)acrylate, 2-hydroxyethyl (meth)acrylate, 2-hydroxypropyl (meth)acrylate, polypropylene glycol di(meth)acrylate, trimethylolpropane di(meth)acrylate, trimethylolpropane tri(meth)acrylate, pentaerythritol tetra(meth)acrylate, and dipentaerythritol hexa(meth)acrylate; epoxy (meth)acrylates such as bisphenol A-type epoxy (meth)acrylate, and bisphenol F-type epoxy (meth)acrylate; and benzocyclobutene resins.

The content of the compound having a polymerizable unsaturated group is preferably 1 to 50 parts by mass based on 100 parts by mass of the total of cyanate ester compound (B) and epoxy compound (C).

The content of the compound having a polymerizable unsaturated group is preferably 1 to 50 parts by mass based on 100 parts by mass of the total of resin solid contents in the resin composition.

### <Filler>

The resin composition of the present embodiment can further contain a filler different from dielectric powder (A), in view of allowing dielectric powder (A), cyanate ester compound (B), and epoxy compound (C) to be even more compatible, obtaining the cured product having even more favorable thermal characteristics, a high glass transition temperature, a low coefficient of thermal expansion, low water absorption, and more favorable dielectric characteristics (high permittivity and low dissipation factor), and obtaining the insulation layer having a more favorable peel strength of the metal foil, and a more suitable surface hardness. The filler is not particularly limited as long as it is different from dielectric powder (A). The fillers can be used singly, or two or more thereof can also be used in combination.

The relative permittivity of the filler different from dielectric powder (A) is preferably less than 20, and more preferably 15 or less. In the present embodiment, the relative permittivity of the filler can be measured and calculated by the same method as for dielectric powder (A) described above.

The median particle size (D50) of the filler is preferably 0.10 to 10.00 μm, and more preferably 0.30 to 5.0 μm. The median particle size (D50) of the filler is calculated in the same manner as for the median particle size (D50) of dielectric powder (A) described above.

Examples of the filler include inorganic fillers such as silica, silicon compounds (e.g., white carbon), metal oxides (e.g., alumina, molybdenum compounds (e.g., molybdic acid, zinc molybdates such as ZnMoO₄ and Zn₃MO₂O₉, ammonium molybdate, sodium molybdate, potassium molybdate, calcium molybdate, molybdenum disulfide, molybdenum trioxide, molybdic acid hydrates, and ammonium zinc molybdate hydrates such as (NH₄)Zn₂MO₂O₉·(H₃O)), zinc oxide, magnesium oxide, and zirconium oxide), metal nitrides (e.g., boron nitride, silicon nitride, and aluminum nitride), metal sulfates (e.g., barium sulfate), metal hydroxides (e.g., aluminum hydroxide, heated products of aluminum hydroxide (e.g., those obtained by heat treating aluminum hydroxide and reducing a part of water of crystallization), boehmite, and magnesium hydroxide), zinc compounds (e.g., zinc borate and zinc stannate), clay, kaolin, talc, calcined clay, calcined kaolin, calcined talc, mica, E-glass, A-glass, NE-glass, C-glass, L-glass, D-glass, S-glass, M-glass G20, glass short fibers (including glass fine powders such as E glass, T glass, D glass, S glass, and Q glass), hollow glass, spherical glass, and metal microparticles formed by insulating a metal such as gold, silver, palladium, copper, nickel, iron, cobalt, zinc, Mn—Mg—Zn, Ni—Zn, Mn—Zn, carbonyl iron, Fe—Si, Fe—Al—Si, and Fe—Ni; and organic fillers, including powders of rubbers such as styrene-based, butadiene-based, and acryl-based rubbers; core/shell rubber powder; silicone resin powder; silicone rubber powder; and silicone composite powder.

Of these, the filler preferably contains one or more selected from the group consisting of silica, alumina, talc, aluminum nitride, boron nitride, boehmite, aluminum hydroxide, zinc molybdate, silicone rubber powder, and silicone composite powder, and more preferably contains silica and/or zinc molybdate.

The filler can be the surface treated filler in which an inorganic oxide is formed on at least a part of the surface of the core particle of the filler. Examples of such a filler include the surface treated molybdenum compound particle (support type) in which an inorganic oxide is formed on at least a part of the surface of core particle made of a molybdenum compound.

The inorganic oxide can be provided on at least a part of the surface of the core particle of the filler. The inorganic oxide can be provided partially on the surface of the core particle of the filler, or can be provided so as to cover the entire surface of the core particle of the filler. The inorganic oxide is uniformly provided so as to cover the entire surface of the core particle of the filler, and specifically, it is preferable that a film of an inorganic oxide be uniformly formed on the surface of the core particle of the filler, in view of obtaining the cured product having more favorable thermal characteristics, a high glass transition temperature, a low coefficient of thermal expansion, low water absorption, and more favorable dielectric characteristics (high permittivity and low dissipation factor), and obtaining the insulation layer having a more favorable peel strength of the metal foil, and a more suitable surface hardness.

Examples of the surface treated molybdenum compound particle (supported type) include those obtained by surface treating particles of a molybdenum compound with a silane coupling agent, and those obtained by treating the surface thereof with an inorganic oxide by the sol-gel method, liquid phase deposition method, or the like.

The inorganic oxide is preferably those with excellent heat resistance. The kind thereof is not particularly limited, but a metal oxide is more preferable. Examples of the metal oxide include SiO₂, Al₂O₃, TiO₂, Zno, In₂O₃, SnO₂, NiO, CoO, V₂O₅, CuO, Mgo, and Zro₂. These can be used singly, or two or more thereof can be appropriately used in combination. Of these, the metal oxide is preferably silica (SiO₂), titanium (TiO₂), alumina (Al₂O₃), and zirconia (Zro₂), in view of heat resistance, insulation characteristic, and cost, for example.

For the surface treated molybdenum compound particles, it is preferable that the inorganic oxide be provided on at least a part of the surface or the entire surface, and specifically at least on a part or the whole of the outer circumference of the core particle made of the molybdenum compound. Of such surface treated molybdenum compounds particles, it is more preferable that silica as the inorganic oxide is provided on at least a part of the surface or the entire surface, and specifically at least on a part or the whole of the outer circumference of core particles made of the molybdenum compound. The core particle made of the molybdenum compound is more preferably at least one selected from the group consisting of molybdic acid, zinc molybdate, and ammonium zinc molybdate hydrate.

The thickness of the inorganic oxide on the surface can be appropriately set in accordance with desired performances and is not particularly limited. The thickness thereof is preferably 3 to 500 nm, in view of forming a uniform film of the inorganic oxide to provide more favorable close contact with the core particle of the filler, obtaining the cured product having more favorable thermal characteristics, a high glass transition temperature, a low coefficient of thermal expansion, low water absorption, and more favorable dielectric characteristics (high permittivity and low dissipation factor), and obtaining the insulation layer having a more favorable peel strength of the metal foil, and a more suitable surface hardness.

In view of the dispersibility in resin composition, the median particle size (D50) of the surface treated molybdenum compound particles is preferably 0.1 to 10 μm. The median particle size (D50) of the surface treated molybdenum compound particles is calculated in the same manner as for the median particle size (D50) of dielectric powder (A) described above.

The core particle made of the molybdenum compound can be produced by various known methods such as crushing method and granulation method, and the production method thereof is not particularly limited. Additionally, a commercial product thereof can be used.

The production method of the surface treated molybdenum compound particle is not particularly limited, and various know techniques, including the sol-gel method, liquid phase deposition method, dip coating method, spray coating method, printing method, electroless plating method, sputtering method, vapor deposition method, ion plating method, and CVD method, can be appropriately employed to provide the inorganic oxide or a precursor thereof on the surface of the core particle made of the molybdenum compound, whereby the surface treated molybdenum compound particles can be obtained. The method for providing the inorganic oxide or a precursor thereof on the surface of the core particle made of the molybdenum compound can be either a wet method or a dry method.

A preferable example of the production method of the surface treated molybdenum compound particle is as follows: the molybdenum compound (core particles) is dispersed in a solution obtained by dissolving a metal alkoxide such as silicon alkoxide (alkoxysilane) or aluminum alkoxide in an alcohol; a mixed solution of water, alcohol, and a catalyst is added dropwise thereto while stirring to hydrolyze the alkoxide, thereby forming a film of silicon oxide or aluminum oxide as a low refractive index film on the surface of the compound; and then the resulting powder is collected by solid-liquid separation, vacuum dried, and then heat-treated. Another preferable example of the production method is as follows: the molybdenum compound (core particles) is dispersed in a solution obtained by dissolving a metal alkoxide such as silicon alkoxide or aluminum alkoxide in an alcohol; the resultant is mixed at a high temperature and a low pressure, thereby forming a film of silicon oxide or aluminum oxide on the surface of the compound; and then the resulting powder is vacuum dried and crushed. By these methods, the surface treated molybdenum compound particles having a film of a metal oxide such as silica, alumina or the others on the surface of the molybdenum compound can be obtained.

The content of the filler is preferably 50 to 300 parts by mass based on 100 parts by mass of the total of cyanate ester compound (B) and epoxy compound (C). The content of the filler is preferably 50 to 300 parts by mass based on 100 parts by mass of the total resin solid content in the resin composition. When two or more kinds of fillers are contained, the total amount can be within the above range.

### <Silane Coupling Agent>

The resin composition of the present embodiment can further contain a silane coupling agent. When the resin composition contains a silane coupling agent, the dispersibility of dielectric powder (A) and the filler to be blended as needed in the resin composition further enhances, thereby tending to further increase the adhesive strength of each component included in the resin composition to the base material to be described later. The silane coupling agents can be used singly, or two or more thereof can also be used in combination.

The silane coupling agent is not particularly limited, and a silane coupling agent generally used for the surface treatment of an inorganic matter can be used. Examples include aminosilane compounds (e.g., 3-aminopropyltriethoxysilane, and N-β-(aminoethyl)-γ-aminopropyltrimethoxysilane), epoxysilane compounds (e.g., 3-glycidoxy propyltrimethoxysilane), acrylsilane compounds (e.g., γ-acryloxypropyl trimethoxysilane), cationic silane compounds (e.g., N-β-(N-vinylbenzylaminoethyl)-γ-aminopropyltrimethoxysilane hydrochloride), styrylsilane compounds, phenylsilane compounds. The silane coupling agents can be used singly, or two or more thereof can also be used in combination. Of these, the silane coupling agent is preferably epoxysilane compounds and styrylsilane compounds. Examples of the epoxysilane compound include “KBM-403” product name), “KBM-303” (product name), “KBM-402” (product name), and “KBE-403” (product name) manufactured by Shin-Etsu Chemical Co., Ltd. Examples of the styrylsilane compound include “KBM-1403” (product name).

The content of the silane coupling agent is not particularly limited, and can be 0.1 to 5.0 parts by mass based on 100 parts by mass of the total of cyanate ester compound (B) and epoxy compound (C). The content of the silane coupling agent is not particularly limited, and can be 0.1 to 5.0 parts by mass based on 100 parts by mass of the total resin solid content in the resin composition.

### <Wetting and Dispersing Agent>

The resin composition of the present embodiment can further contain a wetting and dispersing agent. When the resin composition contains a wetting and dispersing agent, the dispersibility of the filler tends to be more enhanced. The wetting and dispersing agents can be used singly, or two or more thereof can also be used in combination.

The wetting and dispersing agent can be any known dispersing agent (dispersion stabilizer) used for dispersing the filler, and examples include DISPER BYK (registered trademark)-110, 111, 118, 180, 161, 2009, 2152, 2155, W996, W9010, W903 (all product names) manufactured by BYK Japan KK.

The content of the wetting and dispersing agent is not particularly limited, and is preferably 0.5 parts by mass or more and 10 parts by mass or less based on 100 parts by mass of the total of cyanate ester compound (B) and epoxy compound (C). The content of the wetting and dispersing agent is not particularly limited, and is preferably 0.5 parts by mass or more and 10 parts by mass or less based on 100 parts by mass of the total resin solid content in the resin composition.

### <Curing Accelerator>

The resin composition of the present embodiment can further contain a curing accelerator. The curing accelerators can be used singly, or two or more thereof can also be used in combination.

Examples of the curing accelerator include imidazoles such as triphenyl imidazole (e.g., 2,4,5-triphenyl imidazole); organic peroxides such as benzoyl peroxide, lauroyl peroxide, acetyl peroxide, para-chlorobenzoyl peroxide, di-tert-butyl-di-perphthalate; azo compounds such as azobisnitrile; tertiary amines such as N,N-dimethylbenzylamine, N,N-dimethylaniline, N,N-dimethyltoluidine, 2-N-ethylanilino ethanol, tri-n-butylamine, pyridine, quinoline, N-methylmorpholine, triethanolamine, triethylenediamine, tetramethylbutanediamine, and N-methyl piperidine; phenols such as phenol, xylenol, cresol, resorcin, and catechol; organic metal salts such as lead naphthenate, lead stearate, zinc naphthenate, zinc octylate, manganese octylate, tin oleate, dibutyltin maleate, manganese naphthenate, cobalt naphthenate, and acetylacetone iron; those obtained by dissolving these organic metal salts in a hydroxy group-containing compound such as phenol and bisphenol; and inorganic metal salts such as stannous chloride, zinc chloride, and aluminum chloride; and organic tin compounds such as dioctyl tin oxide, other alkyl tins. Of these, triphenyl imidazoles such as 2,4,5-triphenyl imidazole and manganese octylate are preferable because these tend to accelerate the curing reaction to increase the glass transition temperature more.

The content of the curing accelerator is not particularly limited, and is preferably 0.001 parts by mass or more and 1.0 parts by mass or less based on 100 parts by mass of the total of cyanate ester compound (B) and epoxy compound (C). The content of the curing accelerator is not particularly limited, and is preferably 0.001 parts by mass or more and 1.0 parts by mass or less based on 100 parts by mass of the total resin solid content in the resin composition.

### <Solvent>

The resin composition of the present embodiment can further contain a solvent. When the resin composition contains a solvent, the viscosity of the resin composition when preparing reduces, the handleability (operability) further enhances, and the penetrating ability into a base material tends to further enhance. The solvents can be used singly, or two or more thereof can also be used in combination.

The solvent is not particularly limited as long as it can dissolve a part or all of each of the components in the resin composition. Examples include ketones (acetone, and methyl ethyl ketones), aromatic hydrocarbons (e.g., toluene, and xylene), amides (e.g., dimethyl formaldehyde), propylene glycol monomethyl ether, and acetate thereof.

### <Other Components>

The resin composition of the present embodiment can contain components other than above as long as expected characteristics are not affected. Examples of flame retardant compound include bromine compounds such as 4,4′-dibromobiphenyl; nitrogen-containing compounds such as ester phosphate, melamine phosphate, melamine, and benzoguanamine; and silicon compounds. Further, examples of various additives include an ultraviolet absorbent, an antioxidant, a photopolymerization initiator, a fluorescent whitening agent, a photosensitizing agent, a dye, a pigment, a thickener, a lubricant, a defoaming agent, a dispersing agent, a leveling agent (a surface conditioner), a brightening agent, and a polymerization inhibitor.

The content of other components is not particularly limited, and typically 0.01 parts by mass or more and 10 parts by mass or less, respectively, based on 100 parts by mass of the total of cyanate ester compound (B) and epoxy compound (C). The content of other components is not particularly limited, and typically 0.01 parts by mass or more and 10 parts by mass or less based on 100 parts by mass of the total resin solid content in the resin composition.

### [Production Method of the Resin Composition]

The production method of the resin composition of the present embodiment is not particularly limited, and for example, dielectric powder (A), cyanate ester compound (B), epoxy compound (C), and the components described above, as needed, may be mixed and thoroughly stirred. During this operation, known treatments such as stirring, mixing and kneading can be carried out to homogeneously dissolve or disperse each of the components. Specifically, when the stirring and dispersing treatments are carried out using a stirring tank equipped with a stirrer having a reasonable stirring ability, the dispersibility of dielectric powder (C) and the filler to be blended as needed in the resin composition can be enhanced. The above stirring, mixing, and kneading treatments can be appropriately carried out, for example, by using known devices such as a device for the purpose of mixing such as a ball mill, and a bead mill, or a rotation- or revolution-type mixing device.

During the preparation of the resin composition, a solvent is used as needed, so that the resin composition can be prepared in the form of a resin varnish. The kind of the solvent is not particularly limited as long as it can dissolve the resin in the resin composition. Specific examples thereof are as described above. The resin varnish can be obtained typically by adding 10 to 900 parts by mass of a solvent to 100 parts by mass of the components excluding the solvent in the resin, and carrying out the above known treatments (stirring, mixing, and kneading treatments).

### [Usage]

The resin composition of the present embodiment can be suitably used as a material for a cured product, a prepreg, a film-like underfill material, a resin sheet, a laminate, a build-up material, a non-conductive film, a metal foil-clad laminate, a printed wiring board, a fiber-reinforced composite material, or for producing a semiconductor device. Hereinafter, these will be described.

### [Cured Product]

The cured product is obtained by curing the resin composition of the present embodiment. In the production method of the cured product, for example, the resin composition of the present embodiment is fused or dissolved in a solvent, then poured into a mold and cured under typical conditions using heat, light or the like to obtain the cured product. In the case of thermosetting, the curing temperature is preferably in a range from 120 to 300° C., in view of efficiently proceeding the curing and preventing the deterioration of a cured product to be obtained.

### [Prepreg]

The prepreg of the present embodiment contains a base material and the resin composition of the present embodiment penetrating or coating the base material. The prepreg of the present embodiment can be obtained by, for example, allowing the resin composition of the present embodiment (e.g., uncured state (stage A)) to penetrate or coat a base material, and then drying at 120 to 220° C. for about 2 to 15 minutes to semi-cure. In this case, the amount of the resin composition (including the cured product of the resin composition) adhered to the base material, that is, the amount of the resin composition relative to the total amount of the semi-cured prepreg (including the dielectric powder (A) and the filler to be blended as needed), is preferably in a range from 20 to 99 mass %.

The base material is not particularly limited as long as it is a base material used for various printed wiring board materials. Examples of the kind of material of the base material include glass fibers (e.g., E-glass, D-glass, L-glass, S-glass, T-glass, Q-glass, UN-glass, NE-glass, and spherical glass), inorganic fibers other than the glass fibers (e.g., quartz), and organic fibers (e.g., polyimide, polyamide, polyester, liquid crystalline polyester, and polytetrafluoroethylene). The form of the base material is not particularly limited, and examples include woven fabrics, unwoven fabrics, rovings, chopped strand mats, and surfacing mats. These base materials can be used singly, or two or more thereof can also be used in combination. Of these base materials, woven fabrics subjected to super fiber opening treatment and filling treatment are preferable in view of the dimensional stability, and glass woven fabrics surface treated with a silane coupling agent such as epoxysilane treatment and aminosilane treatment are preferable, in view of obtaining the cured product having better thermal characteristics, a high glass transition temperature, low water absorption, a low coefficient of thermal expansion, and more favorable dielectric characteristics (high permittivity and low dissipation factor), and obtaining the insulation layer having a more favorable peel strength of the metal foil, and a more suitable surface hardness. In view of having excellent dielectric characteristic, glass fibers such as E-glass, L-glass, NE-glass, and Q-glass are preferable.

### [Resin Sheet]

The resin sheet of the present embodiment contains the resin composition of the present embodiment. The resin sheet can also be a resin sheet with a support, which contains a support and a layer formed of the resin composition of the present embodiment disposed on the surface of the support. The resin sheet can be used as a build-up film or dry film solder resist. The production method of the resin sheet is not particularly limited, and examples include a method in which a solution of the resin composition of the present embodiment dissolved in a solvent is applied to (coating) the support and dried to obtain the resin sheet.

Examples of the support include, but not limited to, polyethylene films, polypropylene films, polycarbonate films, polyethylene terephthalate films, ethylene tetrafluoroethylene copolymer films, and mold releasing films obtained by coating the surface of any of these films with a mold release agent, organic film base materials such as polyimide films, conductive foils such as copper foil, and aluminum foil, and plate-like supports such as glass plates, SUS plates, and FRP.

Examples of the coating method (applying method) include a method in which a solution of the resin composition of the present embodiment dissolved in a solvent is applied to the support using a bar coater, a die coater, a doctor blade, or a baker applicator. After drying, the support can be released or etched from the resin sheet with the support, in which the support and the resin composition are laminated, to obtain a single layer sheet (resin sheet). For example, the solution of the resin composition of the present embodiment dissolved in a solvent is fed into a mold having a sheet-like cavity and dried to form a sheet-like shape, thereby to obtain a single layer sheet (resin sheet) without using a support.

In the manufacture of the single layer sheet or the resin sheet with the support according to the present embodiment, the drying conditions for removing the solvent are not particularly limited, but the drying is preferably carried out for 1 to 90 minutes at a temperature of 20 to 200° C., in view of easily removing the solvent in the resin composition and inhibiting the progress of curing while drying. In the single layer sheet or the resin sheet with the support, the resin composition can be used in an uncured state after simply drying the solvent, or can be used in a semi-cured state (stage B) as needed. Further, the thickness of the resin layer of the single layer sheet or the resin sheet with the support according to the present embodiment can be adjusted by the concentration and the coating thickness of the solution of the resin composition of the present embodiment, and not particularly limited, and the thickness is preferably, 0.1 to 500 μm in view of easily removing the solvent when drying.

### [Laminate]

The laminate of the present embodiment contains one or more selected from the group consisting of the prepreg and the resin sheet of the present embodiment. In the case of two or more of the prepregs and the resin sheets are laminated, the resin composition used for each prepreg and resin sheet can be the same or different. In the case of using both prepreg and resin sheet, the resin composition used for these can be the same or different. In the laminate of the present embodiment, the one or more selected from the group consisting of the prepreg and the resin sheet can be in a semi-cured state (stage B) or a completely cured state (stage C). The semi-cured state (stage B) refers that each of the components included in the resin composition has not proactively started reacting (curing) while the resin composition is in a dried state, in other words, the resin composition has been heated to the extent that it is no longer viscous in order to volatilize the solvent, and the semi-cured state encompasses a state in which the resin composition is not cured while the solvent has been simply volatilized even without heating. In the present embodiment, the minimum melt viscosity of the semi-cured state (stage B) is typically 20,000 Pas or less. The minimum melt viscosity is, for example, 10 Pas or more in terms of the lower limit. In the present embodiment, the minimum melt viscosity is measured by the following method. Specifically, 1 g of a resin powder collected from the resin composition is used as a sample, and a minimum melt viscosity is measured by a rheometer (ARES-G2 (product name), manufactured by TA Instruments). The minimum melt viscosity of the resin powder herein is measured using a disposable plate having a plate diameter of 25 mm in a range from 40° C. or more and 180° C. or less, under the conditions of a heating rate of 2° C./min, a frequency of 10.0 rad/sec, and a strain of 0.1%.

### [Metal Foil-Clad Laminate]

The metal foil-clad laminate of the present embodiment contains the laminate of the present embodiment and a metal foil disposed on one side or each of both sides of the laminate.

The metal foil-clad laminate can contain at least 1 sheet of the prepreg of the present embodiment and a metal foil laminated on one side or each of both sides of the prepreg.

The metal foil-clad laminate can contain at least 1 resin sheet of the present embodiment and a metal foil laminated on one side or each of both sides of the resin sheet.

In the metal foil-clad laminate of the present embodiment, the resin composition used for each prepreg and resin sheet can be the same or different. In the case of using both prepreg and resin sheet, the resin composition used for these can be the same or different. In the metal foil-clad laminate of the present embodiment, the one or more selected from the group consisting of the prepreg and the resin sheet can be in a semi-cured state or a completely cured state.

In the metal foil-clad laminate of the present embodiment, a metal foil is laminated on one or more selected from the group consisting of the prepreg of the present embodiment and the resin sheet of the present embodiment; however, it is preferable that a metal foil be laminated in such a way as to contact the surface of the one or more selected from the group consisting of the prepreg of the present embodiment and the resin sheet of the present embodiment. “The metal foil be laminated in such a way as to contact the surface of the one or more selected from the group consisting of the prepreg and the resin sheet” means that a layer such as an adhesive layer is not included between the prepreg or resin sheet and the metal foil, but that the prepreg or resin sheet directly contacts the metal foil. Due to this, the peel strength of the metal foil of the metal foil-clad laminate increases, and the insulation reliability of a printed wiring board tends to be enhanced.

The metal foil-clad laminate of the present embodiment can have one or more laminated prepregs and/or resin sheets of the present embodiment and the metal foil(s) disposed on one side or both sides of the prepregs and/or resin sheets. Examples of the production method of the metal foil-clad laminate of the present embodiment include a method in which one or more laminated prepregs and/or resin sheets of the present embodiment, and the metal foil(s) disposed on one side or both sides thereof are laminated. Examples of the formation method include a method typically used when forming a laminate and a multilayer board for a printed wiring board, and more specific examples include a method of laminating using a multistage press machine, a multistage vacuum press machine, a continuous molding machine, or an autoclave molding machine, at a temperature of about 180 to 350° C., for heating time of about 100 to 300 minutes, and a surface pressure of about 20 to 100 kgf/cm².

Further, the prepreg and/or the resin sheet of the present embodiment is laminated in combination with a separately manufactured wiring board for an inner layer to form a multilayer board. In the production method of the multilayer board, for example, copper foils having a thickness of about 35 μm are disposed on both sides of one or more laminated prepregs and/or resin sheets of the present embodiment, and laminated by the above formation method to prepare a copper foil-clad laminate. Then, an inner layer circuit is formed and subjected to blacking treatment to form an inner layer circuit board, and then the inner layer circuit boards and the prepregs and/or resin sheets of the present embodiment are alternately disposed one by one. Further, copper foils are disposed on the outermost layers to laminate under the above conditions, preferably under vacuum, whereby a multilayer board can be manufactured. The metal foil-clad laminate of the present embodiment can be suitably used as a printed wiring board.

### (Metal Foil)

The metal foil is not particularly limited, and examples include a gold foil, a silver foil, a copper foil, a tin foil, a nickel foil, and an aluminum foil. Of these, a copper foil is preferable. The copper foil is not particularly limited as long as it is generally used as a material for a printed wiring board, and examples include copper foils such as a rolled copper foil, and an electrolytic copper foil. Of these, an electrolytic copper foil is preferable, in view of copper foil peel strength and fine wiring formation. The thickness of a copper foil is not particularly limited and can be about 1.5 to 70 μm.

### [Printed Wiring Board]

The printed wiring board of the present embodiment has an insulation layer and a conductor layer disposed on one side or each of both sides of the insulation layer, wherein the insulation layer contains a cured product of the resin composition of the present embodiment. The insulation layer preferably contains at least one of a layer formed of the resin composition of the present embodiment (the layer containing the cured product) and a layer formed of the prepreg (the layer containing the cured product). Such a printed wiring board can be produced according to a usual method, and the production method thereof is not particularly limited. For example, the printed wiring board can be produced by using the metal foil-clad laminate described above. Hereinafter, an example of the production method of the printed wiring board is described.

First, the metal foil-clad laminate described above is provided. Next, the surface of the metal foil-clad laminate is subjected to etching treatment to form an inner layer circuit, thereby manufacturing an inner layer substrate. The surface treatment for increasing the adhesive strength is carried out, as needed, on the inner layer circuit surface of this inner layer substrate, then the required number of sheets of the above prepregs are laminated on the inner layer circuit surface, further a metal foil for an outer layer circuit is laminated on the outside thereof, thereby integrating by heating and pressing. Thus, the multilayer laminate is produced in which the base material and the insulation layer consisting of the cured product of the resin composition of the present embodiment are formed between the inner layer circuit and the copper foil for the outer layer circuit. Subsequently, this multilayer laminate is subjected to drilling for a through-hole or a via hole, then a plated metal film is formed on the wall surface of this hole for conducting the inner layer circuit and the metal foil for the outer layer circuit, further the metal foil for the outer layer circuit is subjected to etching treatment to form the outer layer circuit, whereby the printed wiring board is produced.

The printed wiring board obtained in the above production example has the structure in which the insulation layer and the conductor layer formed on the surface of this insulation layer, wherein the insulation layer contains the cured product of the resin composition according to the present embodiment. That is, the prepreg according to the present embodiment (containing the base material and the cured product of the resin composition of the present embodiment penetrating or coating it) and the layer of the resin composition of the metal foil-clad laminate of the present embodiment (the layer containing the cured product of the resin composition of the present embodiment) are structured by the insulation layer containing the cured product of the resin composition of the present embodiment.

### [Semiconductor Device]

The semiconductor device can be produced by mounting a semiconductor tip at a conductive point on the printed wiring board of the present embodiment. The conductive point herein refers to the point at which an electrical signal is transmitted in the multilayer printed wiring board, and such a place can be either on the surface or in an embedded point. Further, the semiconductor tip is not particularly limited as long as it is an electrical circuit element made of a semiconductor as a material.

The method for mounting a semiconductor tip when producing the semiconductor device is not particularly limited as long as the semiconductor tip effectively functions, and specifically examples include wire-bonding mounting method, flip-chip mounting method, bumpless build-up layer (BBUL) mounting method, anisotropic conductive film (ACE) mounting method, and non-conductive film (NCF) mounting method.

### EXAMPLES

Hereinafter, the present embodiment will be more specifically described by way of examples and comparative examples. The present embodiment is not limited at all by the following examples.

### [Measurement Method of Relative Permittivity (Dk) and Dissipation Factor (Df)]

The relative permittivity (Dk) and the dissipation factor (Df) of the dielectric powder (strontium titanate) were measured by the cavity resonator method in the following manner.

First, 200 mg of a dielectric powder was packed in a PTFE (polytetrafluoroethylene) tube (inner diameter: 1.5 mm, manufactured by NICHIAS Corporation), thereby obtaining a sample for measurement (S). On this sample for measurement (S), the relative permittivity (Dk) and dissipation factor (Df) at 10 GHz were measured using a network analyzer (Agilent 8722ES (product name), manufactured by Agilent Technologies, Inc.). The measurement of the relative permittivity (Dk) and dissipation factor (Df) was carried out under the environment at a temperature of 23° C.±1° C., and a humidity of 50% RH (relative humidity)±5% RH.

Similarly, a PTFE (polytetrafluoroethylene) tube (inner diameter: 1.5 mm, manufactured by NICHIAS Corporation) itself was used as a blank sample (B), and the relative permittivity (Dk) and the dissipation factor (Df) of this sample (B) at 10 GHz were measured.

From these measurement results, using the following Bruggeman formula (ii), the relative permittivity (Dk) and the dissipation factor (Df) of the dielectric powder at 10 GHz were each calculated.

$${f}_{a} \times [ ( {ε}_{a} - {ε}_{d} ) / ( {ε}_{a} + 2 {ε}_{d} ) ] + {f}_{b} \times [ ( {ε}_{b} - {ε}_{d} ) / ( {ε}_{b} + 2 {ε}_{d} ) ] + {f}_{c} \times [ ( {ε}_{c} - {ε}_{d} ) / ( {ε}_{c} + 2 {ε}_{d} ) ] = 0 \qquad Formula ( ii )$$

In the formula (ii), fₐ is the volume fraction (vol %) of PTFE in the sample for measurement, f_{b} is the volume fraction (vol %) of the air in the sample for measurement, f_{c} is the volume fraction (vol %) of the dielectric powder in the sample for measurement, εₐ is the complex permittivity of PTFE, ε_{b} is the complex permittivity of the air, ε_{c} is the complex permittivity of the dielectric powder, and ε_{d} is the complex permittivity of the sample for measurement.

Specifically, first, in the sample (B), the volume fraction f_{bB} of the air was assumed to be 46 (vol %), and the volume fraction f_{aB} of PTFE was assumed to be 54 (vol %). The complex permittivity is represented by the real part and the imaginary part as “ε=ε′−iε″”. Dk is represented by ε′, and Df is represented by ε″/ε′. Accordingly, the complex permittivity ε_{dB} of the sample (B) (including PTFE and air) was calculated from the measurement results of the sample (B) (Dk and Df). Next, the complex permittivity of the air ε_{bB} is 1.0 when the real part and the imaginary part are assumed to be 1.0 and 0, respectively, and thus, the complex permittivity of PTFE εₐ was calculated by assigning f_{aB}, f_{bB}, ε_{dB}, and ε_{bB} to the formula (ii).

Then, for the sample for measurement (S) (including PTFE, air, and dielectric powder), the volume fraction f_{cS} (vol %) of the dielectric powder was calculated from the inner diameter and the length of the PTFE tube, the mass difference between before and after packing the dielectric powder, and the specific gravity of the dielectric powder. On the assumption that the volume fraction f_{aS} of PTFE is 54 (vol %), the volume fraction f_{bS} (vol %) of the air was calculated from the found volume fraction f_{cS}. Next, in the same manner as for the sample (B), the complex permittivity of the sample(S) ε_{dS} (including PTFE, air, and dielectric powder) was calculated from the measurement results (Dk and Df) of the sample for measurement (S). On the assumption that the complex permittivity of the air ε_{b} is 1.0, the complex permittivity of the dielectric powder ε_{c} was calculated by the formula (ii) from εₐ calculated for the sample (B) and f_{aS}, f_{bS}, f_{cS}, and Σε_{dS}. Dk and Df of the dielectric powder were calculated from the calculated &c.

### [Measurement Method of Median Particle Size]

The median particle size (D50) of the dielectric powder (strontium titanate) was calculated by measuring a particle size distribution by the laser diffraction scattering method under the following measurement conditions using a laser diffraction scattering type particle size distribution analyzer (Microtrac MT3300EXII (product name), manufactured by MicrotracBEL Corp.). (Conditions for measurement using a laser diffraction⋅scattering type particle size distribution analyzer)

### (Strontium Titanate)

Solvent: methyl ethyl ketone, solvent refractive index: 1.33, particle refractive index: 2.41, transmittance: 85±5%.

### [Synthesis Example 1] Synthesis of Naphthol Aralkyl-Type Cyanate Ester Compound (SN495V-CN)

300 g of a naphthol aralkyl-type phenolic resin (in terms of OH group 1.28 mol) (SN495V (product name), OH group (hydroxy group) equivalent: 236 g/eq., manufactured by new Nippon Steel Chemical Co., Ltd.) and 194.6 g of triethylamine (1.92 mol) (1.5 mol based on 1 mol of hydroxy group) were dissolved in 1800 g of dichloromethane, and the resultant was designated as Solution 1. 125.9 g of cyanogen chloride (2.05 mol) (1.6 mol based on 1 mol of hydroxy group), 293.8 g of dichloromethane, 194.5 g of 36% hydrochloric acid (1.92 mol) (1.5 mol based on 1 mol of hydroxy group), and 1205.9 g of water were stirred while maintaining the solution temperature at −2 to −0.5° C., into which Solution 1 was pored over a period of 30 minutes. After completion of pouring Solution 1, the resulting solution was stirred at the same temperature for 30 minutes, and a solution in which 65 g of triethylamine (0.64 mol) (0.5 mol based on 1 mol of hydroxy group) was dissolved in 65 g of dichloromethane (Solution 2) was poured thereinto over a period of 10 minutes. After completion of pouring Solution 2, the resultant was stirred for 30 minutes at the same temperature, and the reaction was completed. Subsequently, the reaction liquid was allowed to stand for separating the organic phase and the aqueous phase, and the obtained organic phase was washed 5 times with 1300 g of water. An electrical conductivity of waste water at the 5th water-washing was 5 μS/cm, thereby confirming that ionic compounds removable by washing with water were sufficiently removed. The organic phase after washed with water was concentrated under reduced pressure and finally concentrated to dryness at 90° C. for 1 hour, thereby obtaining 331 g of the intended naphthol aralkyl-type cyanate ester compound (SN495V-CN, cyanate group equivalent: 261 g/eq., R6 in the above formula (1) are all hydrogen atoms, and n2 is an integer of 1 to 10) (orange color viscous substance). An infrared absorption spectrum of the obtained SN495V-CN showed the absorption at 2250 cm⁻¹ (cyanate group), and did not show the absorption of hydroxy group.

### Example 1

A resin varnish was obtained by mixing 53 parts by mass of the naphthol aralkyl-type cyanate ester compound (SN495V-CN, cyanate group equivalent: 261 g/eq.) obtained in Synthesis Example 1, 47 parts by mass of a naphthalene-type epoxy resin (EPICLON (registered trademark) EXA-4032-70M (product name), epoxy equivalent: 150 g/eq., manufactured by DIC corporation), 300 parts by mass of, as the dielectric powder, strontium titanate (SrTiO₃, an oxide of Perovskite structure, median particle size (D50): 1.4 μm, ST-2 (product name), relative permittivity (Dk): 25, dissipation factor (Df): 0.010, manufactured by KCM Corporation), 2 parts by mass of a silane coupling agent (KBM-1403 (product name), manufactured by Shin-Etsu Chemical Co., Ltd.), 6 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.01 parts by mass of manganese octylate (Nikka Octhix Manganese (product name), manufactured by Nihon Kagaku Sangyo Co., Ltd.), and 120 parts by mass of methyl ethyl ketone. The functional group equivalent ratio of cyanate ester compound (B) to epoxy compound (C) in the resin varnish was 0.6.

The obtained resin varnish was allowed to penetrate and coat an E glass cloth (1031NT S640 (product name), manufactured by Arisawa Mfg. Co., Ltd.) having a thickness of 0.094 mm and heated to dry at 130° C. for 3 minutes, thereby obtaining a prepreg having a thickness of 0.1 mm.

Next, electrolytic copper foils (3EC-M3-VLP (product name), manufactured by MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.1 mm. Physical properties of the obtained prepreg, and metal foil-clad laminate were measured in accordance with the evaluation methods, and the measurement results were shown in Table 1.

### Example 2

A resin varnish was obtained in the same manner as in Example 1, except that 47 parts by mass of a biphenyl aralkyl-type epoxy resin (NC-3000FH (product name), epoxy equivalent: 328 g/eq., manufactured by Nippon Kayaku Co., Ltd.) was used instead of using 47 parts by mass of the naphthalene-type epoxy resin (EPICLON (registered trademark) EXA-4032-70M (product name), manufactured by DIC corporation). The functional group equivalent ratio of cyanate ester compound (B) to epoxy compound (C) in the resin varnish was 1.4.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 3

A resin varnish was obtained in the same manner as in Example 1, except that 20 parts by mass of the naphthol aralkyl-type cyanate ester compound (SN495V-CN) obtained in Synthesis Example 1 was used instead of using 53 parts by mass of the naphthol aralkyl-type cyanate ester compound, and that 80 parts by mass of a biphenyl aralkyl-type epoxy resin (NC-3000FH (product name), manufactured by Nippon Kayaku Co., Ltd.) was used instead of using 47 parts by mass of the naphthalene-type epoxy resin (EPICLON (registered trademark) EXA-4032-70M (product name), manufactured by DIC corporation). The functional group equivalent ratio of cyanate ester compound (B) to epoxy compound (C) in the resin varnish was 0.3.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 4

A resin varnish was obtained by mixing 53 parts by mass of the naphthol aralkyl-type cyanate ester compound (SN495V-CN) obtained in Synthesis Example 1, 5 parts by mass of a naphthalene-type epoxy resin (EPICLON (registered trademark) EXA-4032-70M (product name), epoxy equivalent: 150 g/eq., manufactured by DIC corporation), 42 parts by mass of a biphenyl aralkyl-type epoxy resin (NC-3000FH (product name), epoxy equivalent: 328 g/eq., manufactured by Nippon Kayaku Co., Ltd.), 300 parts by mass of, as the dielectric powder, strontium titanate (ST-2 (product name), manufactured by KCM Corporation), 2 parts by mass of the silane coupling agent (KBM-1403 (product name), manufactured by Shin-Etsu Chemical Co., Ltd.), 6 parts by mass of the wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.01 parts by mass of manganese octylate (Nikka Octhix Manganese (product name), manufactured by Nihon Kagaku Sangyo Co., Ltd.), and 120 parts by mass of methyl ethyl ketone. The functional group equivalent ratio of cyanate ester compound (B) to epoxy compound (C) in the resin varnish was 1.2.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 5

A resin varnish was obtained in the same manner as in Example 1, except that 47 parts by mass of a naphthylene ether-type epoxy resin (NC-6000 (product name), epoxy equivalent: 250 g/eq., manufactured by DIC corporation) was used instead of using 47 parts by mass of the naphthalene-type epoxy resin (EPICLON (registered trademark) EXA-4032-70M (product name), manufactured by DIC corporation). The functional group equivalent ratio of cyanate ester compound (B) to epoxy compound (C) in the resin varnish was 1.1.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 6

A resin varnish was obtained by mixing 53 parts by mass of the naphthol aralkyl-type cyanate ester compound (SN495V-CN) obtained in Synthesis Example 1, 44 parts by mass of a naphthalene-type epoxy resin (EPICLON (registered trademark) EXA-4032-70M (product name), epoxy equivalent: 150 g/eq., manufactured by DIC corporation), 3 parts by mass of a butadiene backbone-containing epoxy resin (R-45EPT (product name), epoxy equivalent: 1570 g/eq., manufactured by Nagase ChemteX Corporation), 300 parts by mass of, as the dielectric powder, strontium titanate (ST-2 (product name), manufactured by KCM Corporation), 2 parts by mass of a silane coupling agent (KBM-1403 (product name), manufactured by Shin-Etsu Chemical Co., Ltd.), 6 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.01 parts by mass of manganese octylate (Nikka Octhix Manganese (product name), manufactured by Nihon Kagaku Sangyo Co., Ltd.), and 120 parts by mass of methyl ethyl ketone. The functional group equivalent ratio of cyanate ester compound (B) to epoxy compound (C) in the resin varnish was 0.6.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 7

A resin varnish was obtained in the same manner as in Example 1, except that 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.) was used as the dielectric powder instead of using 300 parts by mass of strontium titanate (ST-2 (product name), manufactured by KCM Corporation). The functional group equivalent ratio of cyanate ester compound (B) to epoxy compound (C) in the resin varnish was 0.6.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 8

A resin varnish was obtained in the same manner as in Example 1, except that 265 parts by mass of barium titanate (BaTio₃, an oxide of Perovskite structure, median particle size (D50): 2.1 μm, relative permittivity (Dk): 10, dissipation factor (Df): 0.007, BT-149 (product name), manufactured by Nippon Chemical Industrial Co., Ltd.) was used as the dielectric powder instead of using 300 parts by mass of strontium titanate (ST-2 (product name), manufactured by KCM Corporation). The amount of barium titanate used was 265 parts by mass so that the volume fraction of the dielectric powder in the resin varnish was equal to that in Example 1, in which strontium titanate was used. The functional group equivalent ratio of cyanate ester compound (B) to epoxy compound (C) in the resin varnish was 0.6.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 9

A resin varnish was obtained in the same manner as in Example 1, except that instead of using 53 parts by mass of the naphthol aralkyl-type cyanate ester compound (SN495V-CN, cyanate group equivalent: 261 g/eq.) obtained in Synthesis Example 1 and 47 parts by mass of the naphthalene-type epoxy resin (EPICLON (registered trademark) EXA-4032-70M (product name), epoxy equivalent: 150 g/eq., manufactured by DIC corporation), 12 parts by mass of a bisphenol A-type cyanate ester compound (Primaset (registered trademark) BADCy (product name), cyanate group equivalent: 139 g/eq., manufacture by Lonza), and 88 parts by mass of a biphenyl aralkyl-type epoxy resin (NC-3000FH (product name), manufactured by Nippon Kayaku Co., Ltd.) were used. The functional group equivalent ratio of cyanate ester compound (B) to epoxy compound (C) in the resin varnish was 0.3.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Comparative Example 1

A resin varnish was obtained by mixing 85 parts by mass of the naphthol aralkyl-type cyanate ester compound (SN495V-CN) obtained in Synthesis Example 1, 15 parts by mass of a naphthalene-type epoxy resin (EPICLON (registered trademark) EXA-4032-70M (product name), epoxy equivalent: 150 g/eq., manufactured by DIC corporation), 300 parts by mass of, as the dielectric powder, strontium titanate (ST-2 (product name), manufactured by KCM Corporation), 2 parts by mass of a silane coupling agent (KBM-1403 (product name), manufactured by Shin-Etsu Chemical Co., Ltd.), 6 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.01 parts by mass of manganese octylate (Nikka Octhix Manganese (product name), manufactured by Nihon Kagaku Sangyo Co., Ltd.), and 120 parts by mass of methyl ethyl ketone. The functional group equivalent ratio of cyanate ester compound (B) to epoxy compound (C) in the resin varnish was 3.0.

Using this resin varnish, a prepreg and a metal foil-clad laminate were obtained in the same manner as in Example 1. Physical properties of the obtained prepreg and metal foil-clad laminate were measured in accordance with the evaluation methods, and the measurement results were shown in Table 2.

### Comparative Example 2

A resin varnish was obtained in the same manner as in Example 1, except that 91 parts by mass of the naphthol aralkyl-type cyanate ester compound (SN495V-CN) obtained in Synthesis Example 1 was used instead of using 53 parts by mass of the naphthol aralkyl-type cyanate ester compound, and that 9 parts by mass of a naphthalene-type epoxy resin (EPICLON (registered trademark) EXA-4032-70M (product name), manufactured by DIC corporation) was used instead of using 47 parts by mass of the naphthalene-type epoxy resin. The functional group equivalent ratio of cyanate ester compound (B) to epoxy compound (C) in the resin varnish was 5.4.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 2.

### Comparative Example 3

A resin varnish was obtained in the same manner as in Example 1, except that 9 parts by mass of the naphthol aralkyl-type cyanate ester compound (SN495V-CN) obtained in Synthesis example 1 was used instead of using 53 parts by mass of the naphthol aralkyl-type cyanate ester compound, and that 91 parts by mass of the naphthalene-type epoxy resin (EPICLON (registered trademark) EXA-4032-70M (product name), manufactured by DIC corporation) was used instead of using 47 parts by mass of the naphthalene-type epoxy resin. The functional group equivalent ratio of cyanate ester compound (B) to epoxy compound (C) in the resin varnish was 0.053.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 2.

### Comparative Example 4

A resin varnish was obtained in the same manner as in Example 1, except that 74 parts by mass of the naphthol aralkyl-type cyanate ester compound (SN495V-CN) obtained in Synthesis Example 1 was used instead of using 53 parts by mass of the naphthol aralkyl-type cyanate ester compound, and that 26 parts by mass of a biphenyl aralkyl-type epoxy resin (NC-3000FH (product name), manufactured by Nippon Kayaku Co., Ltd.) was used instead of 47 parts by mass of the naphthalene-type epoxy resin (EPICLON (registered trademark) EXA-4032-70M (product name), manufactured by DIC corporation). The functional group equivalent ratio of cyanate ester compound (B) to epoxy compound (C) in the resin varnish was 3.6.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 2.

### Comparative Example 5

A resin varnish was obtained in the same manner as in Example 1, except that 80 parts by mass of the naphthol aralkyl-type cyanate ester compound (SN495V-CN) obtained in Synthesis Example 1 was used instead of 53 parts by mass of the naphthol aralkyl-type cyanate ester compound, and that 20 parts by mass of a biphenyl aralkyl-type epoxy resin (NC-3000FH (product name), manufactured by Nippon Kayaku Co., Ltd.) was used instead of 47 parts by mass of the naphthalene-type epoxy resin (EPICLON (registered trademark) EXA-4032-70M (product name), manufactured by DIC corporation). The functional group equivalent ratio of cyanate ester compound (B) to epoxy compound (C) in the resin varnish was 5.0.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 2.

### Comparative Example 6

A resin varnish was used in the same manner as in Example 1, except that 5 parts by mass of the naphthol aralkyl-type cyanate ester compound (SN495V-CN) obtained in Synthesis Example 1 was used instead of using 53 parts by mass the naphthol aralkyl-type cyanate ester compound, and that 95 parts by mass of a biphenyl aralkyl-type epoxy resin (NC-3000FH (product name), manufactured by Nippon Kayaku Co., Ltd.) was used instead of 47 parts by mass of the naphthalene-type epoxy resin (EPICLON (registered trademark) EXA-4032-70M (product name), manufactured by DIC corporation). The functional group equivalent ratio of cyanate ester compound (B) to epoxy compound (C) in the resin varnish was 0.066.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 2.

### [Evaluation Methods]

### (1) Water Absorption Rate

Two sheets of the prepregs obtained in Examples and Comparative Examples were laminated, and electrolytic copper foils (3EC-M3-VLP (product name), manufactured by MITSUI MINING & SMELTING CO., LTD.) having a thickness of 12 μm were disposed on the upper and lower sides thereof. The resultant was subjected to lamination forming by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.2 mm. All the copper foils on both sides of the metal foil-clad laminates were etched, thereby obtaining unclad laminates from which all the copper foils on both sides were removed and having a thickness of 0.2 mm. The unclad laminate was cut (downsized) to a size of 50 mm×50 mm, thereby obtaining a sample for measurement. The sample for measurement was dried in a dryer at 150° C. for 1 hour. Then, the dry mass M1 (g) of the sample for measurement was measured. Next, the sample for measurement after drying was subjected to moisture absorption treatment in a thermo-hygrostat (FX-222P (product name), manufactured by Kusumoto Chemicals, Ltd.) at 85° C. and 85% RH (relative humidity) for 168 hours. After the moisture absorption treatment of 168 hours, the sample for measurement was taken out of the thermo-hygrostat and weighed, and the mass at which the weighing value was constant was used as M2 (g). Using the obtained masses M1 and M2, the water absorption rate (%) was calculated based on the following formula (iii).

$$water absorption rate ( \% ) = [ ( M 2 - M 1 ) / M 1 ] \times 100 \qquad Formula ( iii )$$

### (2) Glass Transition Temperature (Tg)

All the copper foils on both sides of the metal foil-clad laminates obtained in Examples and Comparative Examples were etched, thereby obtaining unclad laminates having a thickness of 0.1 mm from which all the copper foils on both sides were removed. The unclad laminate was cut (downsized) to a size of 40 mm×4.5 mm, thereby obtaining a sample for measurement. On this sample for measurement, the glass transition temperature (Tg, ° C.) was measured by the DMA method in accordance with JIS C6481 using a dynamic mechanical analyzer (Q800 (product name), manufactured by TA Instruments).

### (3) Coefficient of Thermal Expansion (CTE)

All the copper foils on both sides of the metal foil-clad laminates obtained in Examples and Comparative Examples were etched, thereby obtaining unclad laminates having a thickness of 0.1 mm from which all the copper foils on both sides were removed. The unclad laminate was cut (downsized) to a size of 40 mm×4.5 mm, thereby obtaining a sample for measurement. On this sample for measurement, the coefficient of thermal expansion (CTE, ppm/° C.) from 60° C. to 120° C. was measured in accordance with JIS C6481 using a thermomechanical analyzer (Q400 (product name), manufactured by TA Instruments) in a rate of temperature increase of 10° C. based on minute from 40° C. to 340° C. In Comparative Example 3 and Comparative Example 6, the samples were softened in a temperature range from 60° C. to 120° C., and it was thus not possible to measure the coefficient of thermal expansion.

### (4) Copper Foil Peel Strength

Two sheets of the prepregs obtained in Examples and Comparative Examples were laminated, and electrolytic copper foils (3EC-M3-VLP (product name), manufactured by MITSUI MINING & SMELTING CO., LTD.) having a thickness of 12 μm were disposed on the upper and lower sides thereof. The resultant was subjected to lamination forming by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.2 mm. Using the metal foil-clad laminate (10 mm×100 mm×0.2 mm), the copper foil peel strength (copper foil close contact, kgf/cm) was measured in accordance with JIS C6481.

### (5) Relative Permittivity (Dk) and Dissipation Factor (Df)

All the copper foils on both sides of the metal foil-clad laminates obtained in Examples and Comparative Examples were etched, thereby obtaining unclad laminates having a thickness of 0.1 mm from which all the copper foils on both sides were removed. The unclad laminate was cut (downsized) to a size of 1 mm×65 mm, thereby obtaining a sample for measurement.

On this sample for measurement, the relative permittivity (Dk) and dissipation factor (Df) at 10 GHz were each measured using a network analyzer (Agilent 8722ES (product name), manufactured by Agilent Technologies, Inc.). The measurement of the relative permittivity (Dk) and dissipation factor (Df) was carried out under the environment at a temperature of 23° C.±1° C., and a humidity of 50% RH (relative humidity)±5% RH.

### (6) Copper-Clad Solder Heat Resistance (Thermal Characteristics)

Two sheets of the prepregs obtained in Examples and Comparative Examples were laminated, and electrolytic copper foils (3EC-M3-VLP (product name), manufactured by MITSUI MINING & SMELTING CO., LTD.) having a thickness of 12 μm were disposed on the upper and lower sides thereof. The resultant was subjected to lamination forming by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.2 mm. The metal foil-clad laminate was cut (downsized) to a size of 50 mm×50 mm, thereby obtaining a sample for measurement. Three samples for measurement in total were manufactured in the same manner. The samples for measurement were floated in a solder bath at 260° C. so that only one side of the sample contacted the solder for 30 minutes. Thirty minutes later, the sample was taken out of the solder bath to visually observe the side contacted the solder of these samples in terms of the presence or absence in appearance changes. Three samples were each observed. As a result, the case where all samples had no appearance abnormality was rated as “◯”, and the case where 1 or more had appearance abnormality was rated as “X”. For example, when swells were found at the interface of the metal foil and the insulation layer in a sample, it was determined that the sample had appearance abnormality.

TABLE 1

| | | | Example | Example | Example | Example | Example |
|---|---|---|---|---|---|---|---|
| | | | 1 | 2 | 3 | 4 | 5 |
| Varnish | Functional group equivalent ratio | | 0.6 | 1.4 | 0.3 | 1.2 | 1.1 |
| Physical | Water absorption rate [%] (85° C./85%, 168 h) | | 0.27 | 0.24 | 0.19 | 0.22 | 0.23 |
| properties | Glass transition temperature (Tg, ° C.) | | 220 | 222 | 160 | 223 | 248 |
| | Coefficient of thermal expansion [CTE, ppm/° C.] | | 10.5 | 12.2 | 15.9 | 12.1 | 11.3 |
| | Copper foil peel strength [kgf/cm] | | 0.85 | 0.87 | 0.93 | 0.87 | 0.78 |
| | Relative permittivity [Dk, 10 GHz] | | 10.6 | 11.1 | 11.9 | 11.5 | 11.8 |
| | Dissipation factor [Df, 10 GHz] | | 0.021 | 0.020 | 0.022 | 0.020 | 0.021 |
| | Copper-clad solder heat | Floated 260° C., | ◯ | ◯ | ◯ | ◯ | ◯ |
| | resistance | 30 min | | | | | |

| | | Example | Example | Example | Example |
|---|---|---|---|---|---|
| | | 6 | 7 | 8 | 9 |
| Varnish | Functional group equivalent ratio | 0.6 | 0.6 | 0.6 | 0.3 |
| Physical | Water absorption rate [%] (85° C./85%, 168 h) | 0.23 | 0.28 | 0.26 | 0.28 |
| properties | Glass transition temperature (Tg, ° C.) | 220 | 212 | 221 | 150 |
| | Coefficient of thermal expansion [CTE, ppm/° C.] | 10.6 | 11.9 | 11.3 | 15.4 |
| | Copper foil peel strength [kgf/cm] | 0.73 | 0.85 | 0.86 | 0.70 |
| | Relative permittivity [Dk, 10 GHz] | 10.8 | 11.4 | 7.0 | 9.8 |
| | Dissipation factor [Df, 10 GHz] | 0.022 | 0.015 | 0.010 | 0.021 |

| | | | | | |
|---|---|---|---|---|---|
| Copper-clad solder heat | Floated 260° C., | ◯ | ◯ | ◯ | ◯ |
| resistance | 30 min | | | | |

TABLE 2

| | | | Comparative | Comparative | Comparative | Comparative | Comparative | Comparative |
|---|---|---|---|---|---|---|---|---|
| | | | Example 1 | Example 2 | Example 3 | Example 4 | Example 5 | Example 6 |
| Varnish | Functional group equivalent ratio | | 3.0 | 5.4 | 0.053 | 3.6 | 5.0 | 0.066 |
| Physical | Water absorption rate [%] (85° C./85%, 168 h) | | 0.25 | 0.25 | 0.54 | 0.23 | 0.23 | 0.21 |
| properties | Glass transition temperature (Tg, ° C.) | | 241 | 244 | 85 | 225 | 227 | 88 |
| | Coefficient of thermal expansion [CTE, ppm/° C.] | | 11.3 | 11.5 | Not | 11.8 | 11.5 | Not |
| | | | | | measurable | | | measurable |
| | Copper foil peel strength [kgf/cm] | | 0.80 | 0.69 | 0.05 | 0.75 | 0.71 | 0.21 |
| | Relative permittivity [Dk, 10 GHz] | | 11.0 | 9.8 | 9.5 | 11.9 | 11.6 | 11.8 |
| | Dissipation factor [Df, 10 GHz] | | 0.019 | 0.018 | 0.029 | 0.014 | 0.014 | 0.027 |
| | Copper-clad solder heat | Floated 260° C., | X | X | ◯ | X | X | ◯ |
| | resistance | 30 min | | | | | | |

The present application is based on the Japanese Patent Application (No. 2021-174971) filed on Oct. 26, 2021, and the contents of which are incorporated herein by reference.

### INDUSTRIAL APPLICABILITY

The resin composition of the present embodiment can be suitably used as a material for a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device.

1. A resin composition comprising:
(A) a dielectric powder,
(B) a cyanate ester compound, and
(C) an epoxy compound,
wherein a functional group equivalent ratio of a cyanate group of the cyanate ester compound (B) to an epoxy group of the epoxy compound (C)(cyanate group/epoxy group) is 0.1 to 2.0.

2. The resin composition according to claim 1, wherein the dielectric powder (A) comprises one or more selected from the group consisting of titanium dioxide, barium titanate, calcium titanate, and strontium titanate.

3. The resin composition according to claim 1, wherein a median particle size of the dielectric powder (A) is 0.1 to 5 μm.

4. The resin composition according to claim 1, wherein a content of the dielectric powder (A) is 50 to 500 parts by mass based on 100 parts by mass of a total resin solid content in the resin composition.

5. The resin composition according to claim 1, wherein the cyanate ester compound (B) comprises one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallyl bisphenol A-type cyanate ester compounds, and biphenyl aralkyl-type cyanate ester compounds.

6. The resin composition according to claim 1, wherein the epoxy compound (C) comprises one or more selected from the group consisting of biphenyl aralkyl-type epoxy resins, naphthalene-type epoxy resins, naphthylene ether-type epoxy resins, and butadiene backbone-containing epoxy resins.

7. The resin composition according to claim 1, further comprising one or more thermosetting resins or compounds selected from the group consisting of maleimide compounds, modified polyphenylene ether compounds, phenolic compounds, alkenyl-substituted nadiimide compounds, oxetane resins, benzoxazine compounds, and compounds having a polymerizable unsaturated group.

8. The resin composition according to claim 1, further comprising a filler different from the dielectric powder (A).

9. The resin composition according to claim 8, wherein the filler comprises one or more selected from the group consisting of silica, alumina, talc, aluminum nitride, boron nitride, boehmite, aluminum hydroxide, zinc molybdate, silicone rubber powder, and silicone composite powder.

10. The resin composition according to claim 8, wherein a content of the filler is 50 to 300 parts by mass based on 100 parts by mass of a total resin solid content in the resin composition.

11. The resin composition according to claim 1, for use in a printed wiring board.

12. A prepreg, comprising:
a base material, and
the resin composition according to claim 1 penetrating or coating the base material.

13. A resin sheet comprising the resin composition according to claim 1.

14. A laminate comprising the prepreg according to claim 12.

15. A laminate comprising the resin sheet according to claim 13.

16. A metal foil-clad laminate, comprising:
the laminate according to claim 14, and
a metal foil disposed on one side or each of both sides of the laminate.

17. A metal foil-clad laminate, comprising:
the laminate according to claim 15, and
a metal foil disposed on one side or each of both sides of the laminate.

18. A printed wiring board, comprising:
an insulation layer, and
a conductor layer disposed on one side or each of both sides of the insulation layer,
wherein the insulation layer comprises a cured product of the resin composition according to claim 1.
